(19) United States
(12) Patent Application Publication
(10) Pub. No.: US 2009/0085473 A1
(43) Pub. Date: Apr. 2, 2009

(54) ELECTROLUMINESCENT ELEMENT AND MANUFACTURING METHOD THEREOF

(75) Inventors: Yasuhiro Ilzumi, Tokyo-To (JP); Masaya Shimogawara, Tsukuba-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: DAI NIPPON PRINTING CO., LTD., Shinjuku-ku (JP)

(21) Appl. No.: 12/235,056

(22) Filed: Sep. 22, 2008

(30) Foreign Application Priority Data
Sep. 28, 2007 (JP) 2007-256852

(51) Int. Cl. H01J 1/63; B05D 5/06

(52) U.S. Cl. 313/504; 427/66

(57) ABSTRACT

A primary object of this invention is to provide a manufacturing method for an EL element, which can facilitate patterning for a luminescent layer containing quantum dots. This method includes: a wettability-changing-layer-forming step for forming a wettability changing layer containing a photocatalyst, on a substrate having a first electrode layer formed thereon, wherein wettability of the wettability-changing layer is changed by an effect of the photocatalyst associated with irradiation with energy; and a wettability-changing-pattern forming step for forming a wettability changing pattern composed of lyophilic regions and liquid-repellent regions, on a surface of the wettability changing layer, by irradiating the wettability changing layer with energy in a patterning manner. Additionally, in this method, a luminescent layer is formed onto each lyophilic region, by coating a luminescent-layer-forming coating liquid containing the quantum dots, around each of which ligands are attached. In this way, the EL element can be obtained.

### CROSS REFERENCE TO RELATED APPLICATIONS

This application is based on the prior Japanese Patent Application No. 2007-256852 filed on Sep. 28, 2007, the entire contents of which are incorporated herein by reference.

### BACKGROUND OF THE INVENTION

1. Field of the Invention

The present invention relates to a method for manufacturing an electroluminescent element (hereinafter, sometimes referred to as an “EL element”) and also relates to the EL element obtained thereby. This method includes patterning for a luminescent layer containing quantum dots, by using a layer in which wettability can be changed by an effect of a photocatalyst associated with irradiation with energy.

2. Background Art

In the EL element, positive holes and electrons are respectively injected into the luminescent layer from two opposed electrodes and then coupled together in this layer, so that a luminescent material contained in the luminescent layer can be excited by energy generated by the coupling of the positive holes and electrons. Consequently, emission or luminescence with a color corresponding to each luminescent material can be made. Thus, such an EL element has now attracted significant attention as a flat display device of a self-emission type.

Generally, the patterning of the luminescent layer is included in the manufacturing method for the display device using the EL element. As a method for patterning the luminescent layer, various methods, such as a method for depositing the luminescent material via a shadow mask, a method for selectively coating the material by injection, a method for destroying a particular luminescent dye by irradiation with ultraviolet rays, a screen printing method and the like, have been proposed. More specifically, as the method of selectively coating the luminescent material by injection, one exemplary method for obtaining a highly precise fine pattern has been proposed, in which partitions or banks constituting together such a pattern are first formed, and an ink-repellent process is then provided to each surface of the banks (e.g., see Patent Documents 1 and 2). Furthermore, as the method for patterning the luminescent layer, a method which employs a certain photocatalyst that enables formation of such a highly precise fine pattern has been known (e.g., see Patent Documents 3 through 6).

This patterning method employing such a certain photocatalyst utilizes a phenomenon that the wettability of a layer containing the photocatalyst or layer adjacent to the layer containing the photocatalyst will be changed, due to the effect of the photocatalyst, when such a layer is irradiated with particular energy. Namely, with such change of the wettability, a desired pattern can be formed in the luminescent layer. In this way, the method for patterning the luminescent layer by using the photocatalyst can successfully form the pattern, by only utilizing the change or difference of the wettability that can be obtained by the irradiation with energy. This can significantly save time and labor required for the patterning of the luminescent layer.

In recent years, a luminescent element having the luminescent layer containing the quantum dots each composed of a semiconductor material has been proposed and developed. Specifically, each quantum dot is composed of a crystal having a size of approximately several nanometers to several ten nanometers, wherein this crystal is formed from certain atoms that can constitute together the semiconductor material. Such a quite small nano-size crystal does no longer have a continuous energy band structure, but tends to include separated energy levels. Namely, an effect due to the size of each quantum dot (or quantum-dot-size effect) becomes conspicuous. For instance, such a small quantum dot can enhance an effect of confining or capturing electrons (or electron confining effect), as compared with a greater bulky crystal, as such increasing a probability that excitons can be recombined together.

In the luminescent element employing the quantum dots, a frequency of emission can be controlled without changing any construction of the luminescent element. Namely, the quantum dots can exhibit optical properties, based on their own electron confining effect that depends on the size. For instance, a color of emission, due to each quantum dot consisting of CdSe, can be changed from a blue color to a red color, by only selecting the size of this quantum dot. Moreover, each quantum dot can make emission within a relatively narrow half band width, wherein the half band width may be set less than 30 nm. Thus, the quantum dots can be considered as an excellent material for the luminescent layer.

In some cases, the quantum dots are referred to as nano-crystals, fine particles, a colloid, clusters or the like. However, herein, any suitable material can be referred to and/or regarded as the quantum dots, provided that they can exhibit adequate quantum-dot-size effect.

As a method for forming the luminescent layer employing such quantum dots, a spin coating method and/or dip coating method, each employing a colloid solution containing the quantum dots, around each of which ligands, such as tri-n-octylphophine oxide (TOPO) or the like, are attached, has been known (e.g., see Patent Documents 7 and 8). Such legands are attached onto the surface of each quantum dot, so as to enhance stability of dispersion of the quantum dot.

Patent Document 1: JP3601716B

Patent Document 2: JP3646510B

Patent Document 3: JP2001-257073A

Patent Document 4: JP2002-231446A

Patent Document 5: JP2004-71286A

Patent Document 6: JP2005-300926A

Patent Document 7: TOKUHYOU No. 2005-522005, KOHO

Patent Document 8: TOKUHYOU No. 2006-520077, KOHO

However, the method for patterning the luminescent layer containing the quantum dots has been so far scarcely proposed.

### SUMMARY OF THE INVENTION

The present invention was made in light of the above circumstances, and therefore it is a primary object of this invention to provide a new method for manufacturing the EL element, which can facilitate the patterning for the luminescent layer containing the quantum dots.

Through various studies that we have made in order to address the above challenge or provide significantly facilitated patterning for the luminescent layer containing the quantum dots, we have found that it is necessary to maintain a coating liquid in each desired position, by forming a pattern including lyophilic regions and liquid-repellent regions, in advance, on a substrate of the luminescent layer. In addition, we have found that such facilitated patterning for the luminescent layer containing the quantum dots can be achieved, by utilizing a wettability changing layer, which contains the photocatalyst and organopolysiloxane having liquid-repellent properties and thus exhibits a positive-hole transporting function, as well as by applying a photocatalytic function that can be obtained by such a wettability changing layer. Besides, we have found that adhesion properties between materials constituting together the luminescent layer and/or between the luminescent layer and an electrode layer or another additional positive-hole injecting layer can be enhanced, by using a silane coupling agent as the ligands, as such significantly improving the life properties of the EL element. Furthermore, we have found that such utilization of the silane coupling agent as the ligands can render the luminescent layer substantially insoluble to a solvent used in the coating liquid, thereby enabling a coating process to be carried out after a step for forming the luminescent layer.

Namely, the manufacturing method for the EL element according to the present invention comprises: a wettability-changing-layer-forming step for forming the wettability changing layer containing the photocatalyst, on a substrate having a first electrode layer formed thereon, wherein the wettability of the wettability-changing layer is changed by an effect of the photocatalyst associated with irradiation with energy; a wettability-changing-pattern forming step for forming a wettability changing pattern composed of the lyophilic regions and liquid-repellent regions (lyophobic regions), on a surface of the wettability changing layer, by irradiating the wettability changing layer with energy in a patterning manner; and a luminescent-layer-forming step for forming the luminescent layer onto each lyophilic region by coating a luminescent-layer-forming coating liquid containing the quantum dots, around each of which the ligands are attached, to the wettability changing layer with the wettability changing layer.

According to this invention, the wettabiltiy changing pattern is formed by irradiating the wettatility changing layer with proper energy, in a patterning manner. Consequently, the patterning of the luminescent layer can be carried out with ease, by utilizing the difference of wettability created in the wettability changing pattern.

Alternatively, the manufacturing method for the EL element according to the present invention comprises: a wettability-changing-layer-forming step for forming the wettability changing layer, on the substrate having the first electrode layer formed thereon, wherein the wettability of the wettability changing layer is changed by an effect of the photocatalyst associated with irradiation with energy; the wettability-changing-pattern-formign step for forming the wettability changing pattern composed of the lyophilic regions and liquid-repellent regions (lyophobic regions), on the surface of the wettability changing layer, by irradiating the wettability changing layer with energy in a patterning manner, after a photocatalyst-processing-layer base, on which a photocatalyst-processing layer containing at least the photocatalyst is formed, is located over the surface of the wettability changing layer, with a gap that allows the effect of the photocatalyst associated with the irradiation with energy to be exerted on the wettability changing layer; and the luminescent-layer-forming step for forming the luminescent layer onto each lyophilic region by coating the luminescent-layer-forming coating liquid containing the quantum dots, around each of which the ligands are attached,to the wettability changing layer with the wettability changing pattern.

According to this invention, the wettabiltiy changing pattern is formed by irradiating the wettatility changing layer with proper energy, in a patterning manner, via the photocatalyst processing layer. Consequently, the patterning of the luminescent layer can be facilitated, by utilizing the difference of wettability created in the wettability changing pattern. In this case, the photocatalyst is contained in the photocatalyst processing layer, and the photocatalyst-processing-layer base having this photocatalyst processing layer is removed from the wettability changing layer after the wettability-changing-pattern-forming step. Therefore, the photocatalyst is not contained in the wettability changing layer itself, and thus negative influence that may be caused by a barrier layer between the wettabiltiy changing layer and the luminescent layer can be reduced, thereby enhancing emission properties.

In this invention, it is preferred that the ligands include a silane coupling agent. This is because the silane coupling agent contained in the luminescent-layer-forming coating liquid can serve to positively cure the luminescent layer as well as can render the quantum dots in the luminescent layer more stable. As such, the life properties can be significantly enhanced. Generally, molecular design for such a silane coupling agent is carried out with ease. Therefore, by using the silane coupling agent having functional groups for exhibiting a variety of functionality, the life properties can be securely improved. Furthermore, as will be discussed later, in the case in which organopolysiloxane is contained in the wettability changing layer, such organopolysiloxane in the wettability changing layer will be coupled with the first electrode layer while the silane coupling agent in the luminescent layer will be coupled with the wettability changing layer. Consequently, the adhesion properties, between the first electrode, the wettability changing layer and the luminescent layer, can be enhanced.

In this case, the silane coupling agent may include a silicon compound expressed by a general formula: YnSiX(4−n), in which Y is an alkyl group, fluoroalkyl group, vinyl group, amino group, phenyl group or epoxy group, X is an alkoxyl group, acetyl group or halogen, and n is an integer of from 0 to 3. Since the molecular design for such a silicon compound is relatively easy, a degree of condensation or the like factor can be readily controlled by appropriately selecting the groups X, Y. In this way, desired stability of the quantum dots in the luminescent layer can be obtained.

Alternatively, in this case, the silane coupling agent may include a silicon compound expressed by the general formula: YnSiX(4−n), in which Y is a functional group, which can exhibit positive-hole transporting properties, wherein each positive hole can be coupled, directly or via a vinyl group or phenyl group, with this functional group, or another functional group, which can exhibit electron transporting properties, wherein each electron can be coupled, directly or via a vinyl group or phenyl group, with this functional group, or still another functional group, which can exhibit both of the positive-hole transporting properties and electron transporting properties, wherein each positive hole or electron can be coupled, directly or via a vinyl group or phenyl group, with this functional group, X designates an alkoxyl group, acetyl group or halogen, and n is an integer of 0 to 3. Since the molecular design for such a silicon compound is relatively easy, various functional groups having a variety of functionality can be provided thereto. Therefore, the life properties can be significantly ameliorated.

Furthermore, in the above luminescent-layer-forming step, it is preferred that the luminescent-layer-forming coating liquid is cured after it is coated. With this curing process, as described above, the stability of the quantum dots in the luminescent layer can be positively enhanced, as such improving the life properties. In addition, as will be discussed later, in the case in which organopolysiloxane is contained in the wettability changing layer, such organopolysiloxane in the wettability changing layer will be coupled with the first electrode, while the silane coupling agent contained in the luminescent layer will be coupled with the wettability changing layer. Therefore, the adhesion properties, between the first electrode layer, the wettabiltiy changing layer and the luminescent layer, can be positively improved. Moreover, thermo-stability of the luminescent layer (i.e., Tg: glass-transition temperature) can also be improved.

Further, in this invention, it is preferred that each quantum dot is composed of a core portion formed from semiconductor fine particles, and a shell portion formed from a material having an energy band gap greater than that of the semiconductor fine particles. With such construction, each quantum dot can be securely stabilized.

Alternatively, in this invention, the luminescent-layer-forming coating liquid may further contain at least either one of a positive-hole transporting material and an electron transporting material. When such a material is combined with the quantum dots, the steps for manufacturing the EL element can be significantly facilitated, as well as transportation of electric charges into the luminescent layer and energy transfer of the excitons produced by recombination between the positive holes and electrons can be carried out more efficiently. Therefore, the life properties of the EL element can be securely enhanced.

In this invention, it is preferred that a method for coating the luminescent-layer-forming coating liquid includes a discharge method. With such a discharge method, a highly precise fine pattern can be formed by utilizing the wettability changing pattern.

Alternatively or additionally, it is preferred that the wettability changing layer contains organopolysiloxane, which is a condensate obtained through hydrolysis or co-hydrolysis of one or two or more of silicon compounds, each expressed by the general formula: YnSiX(4−n), in which Y is an alkyl group, fluoroalkyl group, vinyl group, amino group, phenyl group or epoxy group, X is an alkoxyl group, acetyl group or halogen, and n is an integer of from 0 to 3. For a material used for the wettability changing layer, it is necessary that the wettability of this material can be changed by an effect of the photcatalyst, and that the bond energy of this material is so high that it cannot be decomposed by the effect of the photcatalyst. Therefore, it is preferable to use the organopolysiloxane that can satisfy the above requirement.

Alternatively, the EL element according to the present invention comprises: the substrate; the first electrode layer formed into a pattern-like shape on the substrate; the wettabiltiy changing layer formed on the first electrode layer such that the wettability of the wettability changing layer is changed by an effect of the photocatalyst associated with irradiation with energy, wherein the wettability changing layer has the lyophilic regions, each located corresponding to the pattern of the first electrode and containing polysiloxane, and has the liquid-repellent regions, each located corresponding to each opening of the pattern of the first electrode layer and containing organopolysiloxane containing fluorine; the luminescent layer formed on each lyophilic regions of the wettability changing layer; and a second electrode layer formed on the luminescent layer, wherein quantum dots, around each of which the silane coupling agent is attached, are used for the luminescent layer.

Generally, fluorine renders the surface energy substantially lowered. Meanwhile, in this invention, each lyophilic regions on the surface of the wettability changing layer contains polysiloxane while each liquid-repellent region contains organopolysiloxane containing fluorine. Thus, critical surface tension of each lyophilic regions should be greater than that of each liquid-repellent region. Therefore, according to this invention, the luminescent layer can be formed only on each lyophilic regions, by utilizing such a difference of wettability between the liquid-repellent regions and the lyophilic regions. As such, the EL element can be provided, in which the patterning for the luminescent layer can be significantly facilitated.

Furthermore, since the quantum dots, around each of which the silane coupling agent is attached, are used in the luminescent layer, the luminescent layer can be positively cured, thus enhancing the stability of the quantum dots in the luminescent layer, thereby improving the life properties of the EL element. In addition, since the molecular design of the silane coupling agent is relatively easy, various functional groups having a variety of functionality can be readily provided to the silane coupling agent. Therefore, the life properties can be further improved. Besides, since organopolysiloxane contained in the wettability changing layer is coupled with the first electrode while the silane coupling agent in the luminescent layer is coupled with the wettabiltiy changing layer, the adhesion properties, between the first electrode layer, the wettability changing layer and the luminescent layer, can be securely enhanced.

In this invention, it is preferred that the luminescent layer contains a condensate obtained through hydrolysis of the silane coupling agent, and is appropriately cured. In this way, the stability of the quantum dots in the luminescent layer can be enhanced, as described above. Thus, the life properties of the EL element can be improved. In addition, the adhesion properties between, the first electrode layer, the wettability changing layer and the luminescent layer, can be significantly enhanced. Moreover, the thermo-stability of the luminescent layer (i.e., Tg: glass-transition temperature) can be ameliorated.

In this case, the condensate obtained through hydrolysis of the silane coupling agent may be organopolysiloxane, which is a condensate obtained through hydrolysis or co-hydrolysis of one or two or more of silicon compounds, each expressed by the general formula: YnSiX(4−n), in which Y is an alkyl group, fluoroalkyl group, vinyl group, amino group, phenyl group or epoxy group, X is an alkoxyl group, acetyl group or halogen, and n is an integer of from 0 to 3. Because the molecular design of such an organopolysiloxane compound is relatively easy, the degree of condensation or the like factor can be readily controlled by appropriately selecting the groups X, Y. In this way, desired stability of the quantum dots in the luminescent layer can be obtained.

Alternatively or additionally, the condensate obtained through hydrolysis of the silane coupling agent may be organopolysiloxane, which is a condensate obtained through hydrolysis or co-hydrolysis of one or two or more of silicon compounds, each expressed by a general formula: YnSiX(4−n), in which Y is a functional group, which can exhibit positive-hole transporting properties, wherein each positive hole can be coupled, directly or via a vinyl group or phenyl group, with this functional group, or another functional group, which can exhibit electron transporting properties, wherein each electron can be coupled, directly or via a vinyl group or phenyl group, with this functional group, or still another functional group, which can exhibit both of the positive-hole transporting properties and electron transporting properties, wherein each positive hole or electron can be coupled, directly or via a vinyl group or phenyl group, with this functional group, X designates an alkoxyl group, acetyl group or halogen, and n is an integer of 0 to 3. Since the molecular design for such organopolysiloxane is relatively easy, various functional groups having a variety of functionality can be provided thereto. Therefore, the life properties of the EL element can be significantly improved.

Further, in this invention, it is preferred that each quantum dot is composed of a core portion formed from semiconductor fine particles, and a shell portion formed from a material having the energy band gap greater than that of the semiconductor fine particles. With such construction, each quantum dots can be securely stabilized.

Therefore, according to the present invention, the wettability changing pattern is formed by irradiating the wettability changing layer with energy in a patterning manner, so that the patterning for the luminescent layer can be significantly facilitated, by utilizing the difference of wettability in the so-formed wettability changing pattern.

### BRIEF DESCRIPTION OF THE DRAWINGS

FIGS. 1(a)-(e) are a flow chart illustrating several steps of one example of the method for manufacturing the EL element according to the present invention.

FIG. 2 is a schematic diagram illustrating a single quantum dot around which the ligands are attached.

FIG. 3 is a schematic cross section showing one example of the EL element according to the present invention.

FIG. 4 is a schematic view illustrating phase separation between a positive-hole transporting layer and the luminescent layer in the EL element according to the present invention.

FIGS. 5(a)-(e) are a flow chart illustrating several steps of another example of the method for manufacturing the EL element according to the present invention.

FIGS. 6(a)-(b) are schematic cross sections illustrating one example of a photocatalyst-processing-layer substrate for use in the present invention.

FIG. 7 is a schematic cross section illustrating another example of the photocatalyst-processing-layer substrate used in the present invention.

FIG. 8 is a schematic cross section illustrating still another example of the photocatalyst-processing-layer substrate used in the present invention.

### DETAILED DESCRIPTION OF THE INVENTION

Hereinafter, the EL element and manufacturing method thereof according to the present invention will be described in detail.

### A. Manufacturing Method for the EL Element

The manufacturing method for the EL element of this invention can be classified into two embodiments, based on construction of the wettability changing layer as well as on steps for forming the wettability changing pattern. Hereinafter, these embodiments will be described separately.

### I. First Embodiment

A first embodiment of the manufacturing method for the EL element of this invention includes: the wettability-changing-layer-forming step for forming the wettability changing layer containing the photocatalyst, on the substrate having the first electrode layer formed thereon, wherein the wettability of the wettability changing layer is changed by an effect of the photocatalyst associated with irradiation with energy; the wettability-changing-pattern forming step for forming the wettability changing pattern composed of lyophilic regions and liquid-repellent regions, on the surface of the wettability changing layer, by irradiating the wettability changing layer with energy in a patterning manner; and the luminescent-layer-forming step for forming the luminescent layer by coating the luminescent-layer-forming coating liquid containing the quantum dots, around each of which the ligands are attached, onto each lyophilic region.

Hereinafter, the manufacturing method for the EL element of this embodiment will be described with reference to the drawings.

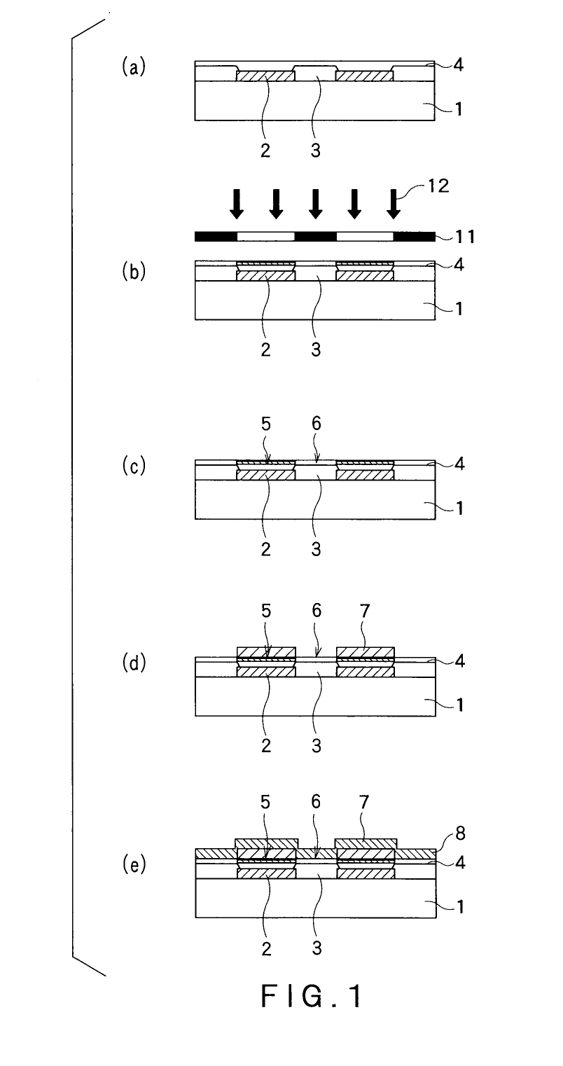

FIG. 1 is a flow chart illustrating several steps of one example of the manufacturing method for the EL element related to this embodiment. First, a first electrode layer 2 is formed into a pattern-like shape on a substrate 1. Then, an insulating layer 3 is formed at each opening of the pattern. Thereafter, a wettability changing layer 4 is formed on the first electrode layer 2 and each insulating layer 3 (FIG. 1(a): the wettability-changing-layer-forming step).

Subsequently, the wettability changing layer 4 is irradiated with ultraviolet rays 12 via a photomask 11 (FIG. 1(b)). Due to such irradiation with the ultraviolet rays 12, the wettability is changed such that the contact angle relative to the liquid will be lowered, in each irradiated portion of the wettability changing layer 4, by an effect of the photocatalyst contained in the wettability changing layer 4 (FIG. 1(c)). The portions or regions in which the wettability is changed such that the contact angle relative to the liquid is lowered will be referred to as “lyophilic regions 5.” It is noted that the wettability is not changed in each non-irradiated portion. Such portions or regions, in which the wettability is not changed, will be referred to as “liquid-repellent regions 6.” In this way, the wettability-changing pattern composed of the lyophilic regions 5 and liquid-repellent regions 6 is formed on the surface of the wettability changing layer 4. Namely, FIGS. 1(b) and 1(c) show the wettability-changing-pattern-forming step, respectively.

In the wettability changing layer 4, the photocatalyst is contained such that the wettability of the layer 4 can be changed by the effect of the photocatalyst associated with the irradiation with energy. Therefore, there is a substantial difference in the wettability between the lyophilic regions 5 respectively corresponding to the irradiated portions and the liquid-repellent regions 6 respectively corresponding to the non-irradiated portions.

Thereafter, the luminescent-layer-forming coating liquid is coated on the wettability changing layer pattern composed of the lyophilic regions 5 and liquid-repellent regions 6, so as to form a patterned luminescent layer 7 formed only on each lyophilic regions 5, by utilizing the difference in the wettability (FIG. 1(d): the luminescent-layer-forming step).

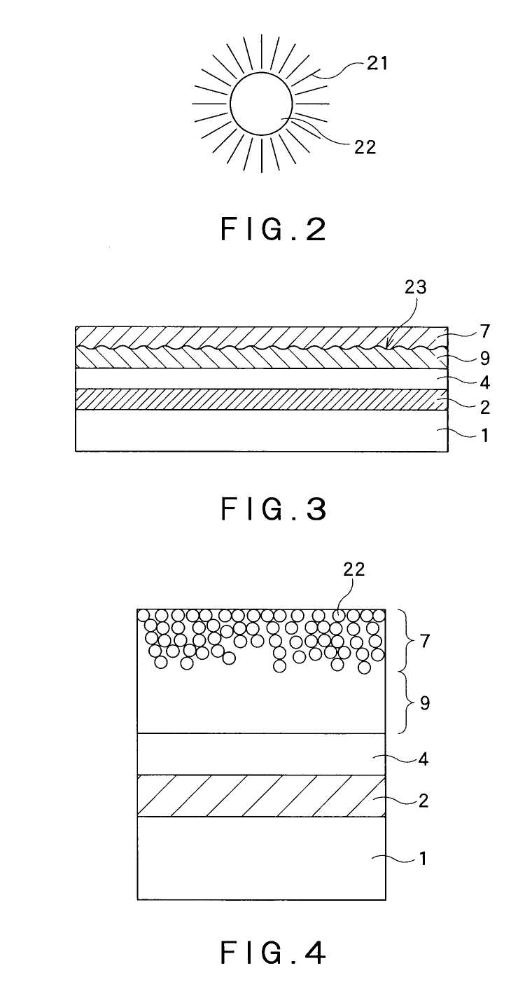

The luminescent-layer-forming coating liquid contains the quantum dots 22, around each of which the ligands 21 are attached, as shown in FIG. 2. Namely, the ligands 21 are attached to a surface of each quantum dot 22, and such quantum dots 22, around each of which the ligands 21 are attached, are contained in the luminescent-layer-forming coating liquid.

Thereafter, a second electrode 8 is formed on the luminescent layer 7 (FIG. 1(e): a second-electrode-layer-forming step). Upon this step, for example, in the case in which an optically transparent electrode is used as the second electrode 8, a top-emission-type EL element can be obtained. However, in the case in which such an optically transparent electrode is used as the first electrode 2, a bottom-emission-type EL element can be obtained.

In this embodiment, the wettability changing pattern composed of the lyophilic regions and liquid-repellent regions is formed on the surface of the wettability changing layer, by irradiating the wettability changing layer containing the photocatalyst, with energy, in a patterning manner. Thereafter, the patterning of the luminescent layer is carried out, by utilizing the wettability changing pattern formed on the surface of the wettability changing layer. Accordingly, such patterning of the luminescent layer can be carried out with ease, without a need for performing complicated patterning steps and/or preparing additional expensive vacuum equipment.

In this embodiment, as will be detailed later, it is preferred that the ligands attached to the surface of each quantum dot are formed from a silane coupling agent. Consequently, the luminescent layer can be provided as a cured form, thus enhancing the stability of each quantum dot in the luminescent layer, thereby improving the life properties. Generally, the molecular design for such a silane coupling agent can be carried out with ease. Therefore, by using the silane coupling agent having functional groups for exhibiting a variety of functionality, the life properties can be securely ameliorated.

Furthermore, as will be detailed later, it is preferred that the wettability changing layer contains organopolysiloxane. In this case, the organopolysiloxane contained in the wettability changing layer will be coupled with the first electrode layer, while the silane coupling agent contained in the luminescent layer will be coupled with the wettability changing layer. Thus, the adhesion properties, between the first electrode layer, the wettability changing layer and the luminescent layer, can be positively enhanced. Accordingly, degradation of the life properties caused by interlayer peeling or detachment during operation of the EL element and the like can be prevented.

Hereinafter, each step of the manufacturing method for the EL element will be further described.

### 1. Wettability-Changing-Layer-Forming Step

In the wettability-changing-layer-forming step of this invention, the wettability changing layer, which contains the photocatalyst and in which the wettability is changed by the effect of the photocatalyst associated with irradiation with energy, is formed on the substrate having the first electrode layer formed thereon.

Hereinafter, the wettability changing layer, method for forming the wettability changing layer, substrate and first electrode layer will be described, respectively.

### (1) Wettability Changing Layer

As the wettability changing layer of this embodiment, any suitable layer can be used, provided that it can contain the photocatalyst and its wettability can be properly changed by the effect of the photocatalyst associated with the irradiation with energy. For instance, the wettability changing layer may be a single layer, which contains the photocatalyst and in which the wettability can be changed by the effect of the photocatalyst associated with the irradiation with energy (i.e., a first aspect), or otherwise may be provided as a composite layer, in which one layer containing the photocatalyst and another layer having the wettability that can be changed by the effect of the photocatalyst associated with the irradiation with energy are laminated together (i.e., a second aspect). Hereinafter, the first and second aspects will be described, respectively.

### (i) Firs Aspect

The wettability changing layer in the first aspect is the single layer which contains the photocatalyst and in which wettability can be changed by the effect of the photocatalyst associated with the irradiation with energy. This wettability changing layer exhibits the wettability that can be changed by the effect of the photocatalyst contained in such a wettability changing layer itself. Therefore, the wettabiltiy changing pattern can be formed efficiently.

As the wettability changing layer in this aspect, any suitable layer can be used, provided that it can contain the photocatalyst, and that its wettability can be properly changed by the effect of the photocatalyst associated with the irradiation with energy. Usually, this layer contains the photocatalyst and a material, the wettability of which can be changed by the effect of the photocatalyst.

As the photocatalyst, a material that is known as a photo-semiconductor, such as titanium dioxide (TiO₂), zinc oxide (ZnO), tin oxide (SnO₂), strontium titanate (SrTiO₃), tungsten oxide (WO₃), bismuth oxide (Bi₂O₃), and ferric oxide (Fe₂O₃), can be mentioned. Such materials may be used alone or as a mixture of two or more of them.

Among them, the titanium dioxide is preferred because it has a higher energy band gap, exhibits good chemical stability and no toxicity, and is available with ease. The titanium dioxide includes an anatase type and a rutile type, both of which can be used herein. Of these types, the anatase-type titanium dioxide is preferred. This is because such anatase-type titanium dioxide has an excitation wavelength of 380 nm of less.

As the anatase-type titanium dioxide, for example, an anatase-type titaniasol that can be dissolved and/or adhered in the presence of hydrochloric acid (produced by ISHIHARA SANGYO Co. Ltd., STS-02 (average particle size: 7 nm), or produced by ISHIHARA SANGYO Co. Ltd., ST-K01), an anatase-type titaniasol that can be dissolved and/or adhered in the presence of nitric acid (e.g., produced by NISSAN KGAKU Co. Ltd., TA-15 (average particle size: 12 nm)) and the like can be mentioned.

With a smaller particle size, a photocatalyst reaction can be performed more effectively. Therefore, it is preferable to use the photocatalyst having a smaller particle size. Preferably, the average particle size of the photocatalyst is 50 nm or less, more preferably 20 nm or less.

While still being elucidated, a mechanism of the effect of the photocatalyst represented by the above titanium dioxide can be considered as one in which the photocatalyst may first cause an oxidation-reduction reaction with the irradiation with energy, as such active oxygen species, such as super oxide radicals (.O₂⁻) and/or hydroxyl radicals (.OH) will be generated, and eventually the so-generated active oxygen species may change a chemical structure of an organic material. In this embodiment, such active oxygen species can be considered to exert some effect on the organic material present in the wettability changing layer.

The content of the photocatalyst in the wettability changing layer may be set within a range of from 5% by weight t 90% by weight, and preferably within a range of from 20% by weight to 70% by weight.

It is noted that the content and crystal type of the titanium dioxide in the wettability changing layer can be determined, by using the X-ray photoelectron spectrometry, Rutherford back-scattering spectrometry, nuclear magnetic resonance spectrometry or mass spectrometry, alone or in a combination thereof.

As the material exhibiting the wettability that can be changed by the effect of the photocatalyst associated with the irradiation with energy, any suitable material may be used, provided that it has a main chain that is not likely degraded and/or decomposed by the effect of the photocatalyst. As such a material, for example, (1) organopolysiloxane, which can be obtained through hydrolysis and polycondensation of chloro- or alkoxy-silanes and the like monomers in a sol-gel reaction or the like, thus exhibiting considerably high strength, (2) organopolysiloxane, in which reactive silicones, each having excellent water-repellent properties and/or oil-repellent properties, are cross-linked together, and the like organopolysiloxane can be mentioned.

In the case (1) described above, the organopolysiloxane is preferably a condensate obtained through hydrolysis or co-hydrolysis of one or two or more of silicon compounds, each expressed by the following general formula:

YnSiX(4−n),

in which Y is an alkyl group, fluoroalkyl group, vinyl group, amino group, phenyl group or epoxy group, X is an alkoxyl group, acetyl group or halogen, and n is an integer of from 0 to 3. The number of carbon atoms included in the group designated by Y is preferably within a range of from 1 to 20. Preferably, the alkoxyl group designated by X is a methoxy group, ethoxy group, propoxy group or butoxy group. Specifically, as the silicon compound expressed by the above general formula, those disclosed in JP2000-249821A can be used.

Especially, it is preferable to use polysiloxane containing the fluoroalkyl group. As the polysiloxane containing the fluoroalkyl group, for example, a condensate obtained through hydrolysis or co-hydrolysis of one or two or more of fluoroalkylsilanes as described in JP2000-249821A can be mentioned. Usually, a material, which is generally known as a fluoro-type silane coupling agent can be used.

By using the polysiloxane containing the fluoroalkyl group, the liquid-repellent properties in the wettability changing layer can be significantly enhanced. Thus, in this way, film formation of the luminescent layer on each liquid-repellent region, in which the wettability will not be changed, can be securely avoided. Therefore, the luminescent layer can be formed only on each lyophilic regions in which the wettability is changed such that the contact angle relative to the liquid can be lowered.

Whether or not the polysiloxane containing the fluoroalkyl group is contained in the wettability changing layer can be observed by the X-ray photoelectron spectrometry, Rutherford back-scattering spectrometry, nuclear magnetic resonance spectrometry or mass spectrometry.

As the reactive silicone in the case (2) described above, a compound having a skeleton expressed by the following chemical formula can be mentioned.

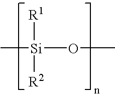

In the above chemical formula, n is an integer of 2 or greater, R¹, R² are independently a substituted or non-substituted alkyl group, alkenyl group, aryl group or cyanoalkyl group, each having 1 to 10 carbon atoms, with vinyl groups, phenyl groups and/or halogenated phenyl groups included in the above skeleton at a molar ratio of 40% or less. Preferably, R¹, R² are both methyl groups because such a molecular structure can make the surface energy the minimum. In this case, the methyl groups are preferably included in the above skeleton at a molar ratio of 60% or greater. In addition, this skeleton includes at least one reactive group, such as a hydroxyl group or the like, in its molecular chain, e.g., at its terminal ends and/or side chains.

Alternatively or additionally, a relatively stable organosilicone compound (e.g., dimethylpolysiloxane) that causes no cross-linking reaction, may be mixed with the aforementioned organopolysiloxane.

In this way, various materials, such as organopolysiloxane and the like, can be used for the wettability changing layer. Especially, it is preferred that the wettability changing layer contains fluorine. In this case, the content of fluorine in the wettability changing layer is preferably decreased, due the effect of the photocatalyst associated with the irradiation with energy, as compared with the content prior to the irradiation with energy.

Since fluorine renders the surface energy substantially lowered, a surface of a material containing a lot of fluorine generally tends to exhibit significantly reduced critical surface tension. Therefore, the critical surface tension in a portion of the surface containing less fluorine should be greater than that in another portion of the surface containing more fluorine.

Namely, in the wettability changing layer as described above, the wettability changing pattern can be provided, which includes the portions (i.e., the lyophilic regions) each corresponding to the portion irradiated with energy and thus containing less fluorine and the other portions (i.e., the liquid-repellent regions) each corresponding to the portion not irradiated with the energy and thus containing more fluorine. Thus, it is advantageous to use the wettability changing layer containing fluorine, for the formation of the wettability changing pattern.

Other than the materials described above, suitable surfactants and/or other additives, as described in JP2000-249821A, may be added to the wettability changing layer.

Such a wettability changing layer can be formed by preparing the wettability-changing-layer-forming coating liquid by dissolving and/or dispersing the aforementioned materials in a solvent, together with other additives if required, and then coating the so-prepared wettability-changing-layer-forming coating liquid onto the electrode layer.

As the solvent that can be used for preparing the wettability-changing-layer-forming coating liquid, any suitable solvent can be used, provided that it can be mixed with the aforementioned materials without causing any disadvantage to the patterning properties, such as cloudiness or the like phenomenon. As such a solvent, for example, alcohols, such as methanol, ethanol, isopropanol and butanol, acetone, acetonitrile, ethylene glycol monomethyl ether, ethylene glycol dimethyl ether, ethylene glycol monoethyl ether, ethylene glycol monoethyl ether acetate, diethylene glycol monomethyl ether, diethylene glycol monoethyl ether, diethylene glycol monoethyl ether acetate, propylene glycol monomethyl ether, propylene glycol monoethyl ether, propylene glycol monomethyl ether acetate, methyl acetate, ethyl acetate, butyl acetate, toluene, xylene, methyl lactate, ethyl lactate, ethyl pyruvate, methyl 3-methoxypropionate, ethyl 3-ethoxypropionate, dimethylformamide, dimethyl sulfoxide, dioxane, ethylene glycol, hexamethylphosphoric triamide, pyridine, tetrahydrofuran, N-methylpyrrolidone, and the like can be mentioned. Such solvents may be used as a mixture of two of more thereof.

As a coating method for the wettability-changing-layer-forming coating liquid, for example, the spin coating method, injection method, casting method, LB method, dispenser method, micro-gravure coating method, gravure coating method, bar coating method, roll coating method, wire-bar coating method, dip coating method, flexographic printing, screen printing and the like can be mentioned.

After the wettability-changing-layer-forming coating liquid is coated, the resultant coated film may be dried. As a method for drying the film, any suitable method can be employed, provided that it can form a uniform wettability changing layer. For instance, a hot plate, an infrared heater, an oven or the like means can be used.

In regard to the film thickness of the wettability changing layer, any suitable film thickness can be selected, provided that it will not interfere with the transportation of the positive holes and/or electrons. Preferably, the film thickness is within a range of from 10 nm to 500 nm, for example, 10 nm to 200 nm, and especially 10 nm to 100 nm. If the wettability changing layer is unduly thin, it would be quite difficult to obtain an adequately uniform film thickness. Meanwhile, if the wettability changing layer is excessively thick, such a layer may tend to substantially interfere with transfer of the positive holes and/or electrons.

### (ii) Second Aspect

In the wettability changing layer of this aspect, the one layer containing the photocatalyst and the other layer having the wettability that can be changed by the effect of the photocatalyst associated with the irradiation with energy are laminated together. Namely, the wettability changing layer of this aspect has the two layers each used for each function. Therefore, such layered configuration and/or combination of the materials can be readily changed as desired. Hereinafter, each component of the wettability changing layer will be discussed.

### (Layer Containing the Photocatalyst)

As the one layer containing the photocatalyst used for this aspect, any suitable layer can be employed, provided that it can contain the photocatalyst such that the photocatalyst contained therein can change the wettability of the other laminated layer having the wettability that can be changed.

The layer containing the photocatalyst may further contain a binder. In this way, the film formation can be facilitated. As the binder used for this aspect, any suitable material can be used, provided that a main skeleton thereof has such higher bond energy that it will not be decomposed by photo-excitation due to the photocatalyst. For instance, alkyl silicates can be used as the binder. As such an alkyl silicate, a compound that can be expressed by a general formula: SiₙOₙ₋₁(OR)₂ₙ₊₂ (in which, Si is silicon, O is oxygen, and R is an alkyl group) can be mentioned. In this case, it is preferred that n is an integer within a range of from 1 to 6 and R is an alkyl group having 1 to 4 carbon atoms. More preferably, the ratio of silicon atoms in this molecule is relatively high. In addition, the material having the wettability that can be changed by the effect of the photocatalyst associated with the irradiation with energy, as described in the first aspect, can also be used.

It is noted that the wettability of the surface of the layer containing the photocatalyst may exhibit either of the liquid-philic properties or liquid-repellent properties.

Any suitable thickness of the layer containing the photocatalyst can be employed, provided that it will not interfere with the transportation or transfer of the positive holes and/or electrons. Preferably, this thickness is within a range of from 10 nm to 500 nm, for example, 10 nm to 200 nm, and especially 10 nm to 100 nm. If the layer containing the photocatalyst is unduly thin, it would be quite difficult to change the wettability of the layer having the wettability that can be changed. Meanwhile, if the layer containing the photocatalyst is excessively thick, the transfer efficiency of the positive holes and/or electrons may be substantially deteriorated.

(Layer Having the Wettability that can be Changed)

As the layer having the wettability that can be changed for use in this aspect, any suitable layer can be employed, provided that the wettability of this layer can be changed by the effect of the photocatalyst associated with the irradiation with energy. Usually, this layer contains the material having the wettability that can be changed by the effect of the photocatalyst associated with the irradiation with energy. It is noted that the material having the wettability that can be changed by the effect of the photocatalyst associated with the irradiation with energy may be the same as that discussed in the first aspect. Therefore, the description on this material is now omitted.

Again, as with the first aspect, the layer having the wettability that can be changed may include a suitable surfactant or other additives.

In regard to the thickness of the layer having the wettability that can be changed, any suitable thickness can be employed, provided that it enables the wettability changing pattern to be formed, and that it will not interfere with the transportation of the positive holes and/or electron. Preferably, this thickness is within a range of from 0.5 nm to 20 nm, for example, 0.5 nm to 10 nm. If the wettability changing layer is unduly thin, the difference of the wettability may not be clearly expressed. Meanwhile, if the wettability changing layer is too thick, the efficiency of transportation of the positive holes and/or electrons may be considerably deteriorated.

### (2) Substrate

The substrate used for this embodiment may not have optical transparency. For instance, in the case of manufacturing a bottom-emission-type element as the EL element shown in FIG. 1(e), the substrate 1 preferably exhibit the optical transparency. On the other hand, in the case of manufacturing a top-emission-type element as the EL element shown in FIG. 1(e), the optical transparency is not required for the substrate 1. Furthermore, in the case of outputting light from both faces of the EL element shown in FIG. 1(e), the substrate 1 preferably has the optical transparency.

As the substrate having the optical transparency, for example, inorganic materials, such as glass, etc., transparent resins and the like can be employed.

As the optically transparent resin, any suitable resin can be used, provided that it can be formed into a film. Preferably, this resin has higher optical transparency, excellent solvent resistance and heat resistance. As such a resin, for example, polyether sulfone, polyethylene terephthalate (PET), polycarbonate (PC), polyetheretherketone (PEEK), polyvinylidene fluoride (PFV), polyacrylate (PA), polypropylene (PP), polyethylene (PE), amorphous polyolefines, fluoro-resins and the like can be mentioned.

### (3) First Electrode

The first electrode used in this embodiment may be either of the anode or cathode. Generally, upon manufacturing the EL element, lamination that is started from the side of the anode can produce the EL element more stably. Therefore, it is preferable to use the first electrode as the anode.

In order to facilitate injection or introduction of the positive holes, it is preferred that an electrically conductive material having greater work function is used as the anode. On the other hand, another electrically conductive material having relatively lower work function is used as the cathode in order to facilitate injection of the electrons. As such an electrically conductive material, a metallic material is generally used, while a suitable organic material or inorganic compound may also be used. Alternatively, as the first electrode layer, a plurality of materials may be used in a mixed form.

The first electrode layer may have or may not have optical transparency. This is suitably determined, depending on a face for outputting the light. For instance, in the case of manufacturing the bottom-emission-type element as the EL element shown in FIG. 1(e), the first electrode 2 preferably exhibit the optical transparency. On the other hand, in the case of manufacturing the top-emission-type element as the EL element shown in FIG. 1(e), the optical transparency is not required for the first electrode 2. Furthermore, in the case of outputting the light from both faces of the EL element shown in FIG. 1(e), the first electrode 2 preferably has the optical transparency.

As a suitable electrically conductive material having the optical transparency, In—Zn—O (IZO), In—Sn—O (ITO), Zn—O—Al, Zn—Sn—O or the like material can be mentioned. Otherwise, in the case in which the optical transparency is not required, a usual metallic material can be used as the electrically conductive material. For instance, Au, Ta, W, Pt, Ni, Pd, Cr, or Al alloy, Ni alloy, Cr alloy or the like can be mentioned as such a metallic material.

It is preferred that the electrical resistance of the first electrode layer is relatively low, regardless of the anode or cathode.

As the method for forming the first electrode layer, a commonly known film-forming method for the electrode can be used. For instance, the spattering method, ion-plating method, vacuum deposition or the like can be mentioned. As the patterning method for the first electrode layer, the photolithography can be mentioned.

### 2. Wettability-Changing-Pattern-Forming Step

In the wettability-changing-pattern-forming step of this embodiment, the wettability changing pattern composed of the lyophilic regions and liquid-repellent regions respectively provided on the surface of the wettability changing layer is formed, by irradiating the wettability changing layer with proper energy in a patterning manner.

The wavelength of light used for the irradiation with energy is usually set at 450 nm or less, and preferably 380 nm or less. This is because the photocatalyst preferably used for the wettability changing layer is titanium dioxide as described above. Namely, the wavelength of light within the aforementioned range is especially suitable as the energy for activating the effect of the photocatalyst consisting of the titanium dioxide.

As a light source that can be used for the irradiation with such energy, a mercury lamp, a metal-halide lamp, a xenon lamp, an excimer lamp and the like can be mentioned.

As a method for radiating the energy in a patterning manner, a method for irradiating the energy, using the light source as described above via a suitable patterning photomask, may be used. Otherwise, a method for radiating the energy to depict a desired pattern, by using an excimer, YAG or the like laser, can be used.

The amount of the irradiation with energy is set at a value required for changing the wettability of the surface of the wettability changing layer due to the effect of the photocatalyst contained in the wettability changing layer.

Upon this irradiation, it is preferable to irradiate the wettability changing layer with energy while heating this layer. This is because the sensitivity to light can be significantly enhanced, thereby to effectively change the wettability. More specifically, it is preferable to heat the layer within a temperature range of from 30° C. to 80° C.

Any suitable method for the irradiation with energy can be used, provided that it can adequately change the wettability of the wettability changing layer. Alternatively or additionally, the irradiation with energy may use a proper mask, such as the photomask, in which a desired or aimed pattern is formed in advance. In this way, the energy can be applied to the layer through the mask having such an aimed pattern, so that the wettability of the wettability changing layer can be changed into a desired patterning manner. For this operation, any kind of masks can be used, provided that the energy can be applied, therethrough, in the aimed pattern, to the wettability changing layer. For instance, the photomask may be formed of a material through which the energy can be transmitted, with light shielding portions formed in proper positions. Alternatively, the photmask may be a shadow mask or the like member, in which holes are formed, corresponding to the aimed pattern. As a material for such masks, for example, an inorganic material, such as glass or ceramic, or otherwise an organic material, such as plastics, or the like, can be mentioned.

As a direction in which the irradiation with energy is performed, either of directions for irradiation on the side of the substrate or on the side of the wettability changing layer can be selected. Of course, in the case in which the photmask is used, the irradiation with energy should be performed on the side that the photomask is located.

As used herein, the term “lyophilic regions” means regions in which the contact angle relative to the liquid is significantly less than that measured in the liquid-repellent regions. Therefore, such lyophilic regions can be considered to have better wettability to the luminescent-layer-forming coating liquid. On the other hand, the term “liquid-repellent regions” means regions in which the contact angle relative to the liquid is significantly greater than that measured in the liquid-phllic regions. Therefore, such liquid-repellent regions can be considered to have significantly poor wettability to the luminescent-layer-forming coating liquid. Further, as used therein, one region exhibiting the contact angle greater by 1° than that of other regions adjacent to this region will be referred to and considered as the “lyophilic regions,” while one region exhibiting the contact angle smaller by 1° than that of other regions adjacent to this region will be referred to and considered as the “liquid-repellent region.”

In each liquid-repellent region, it is preferred that the contact angle relative to a certain liquid having the surface tension equivalent to that of the luminescent-layer-forming coating liquid is 21° or greater, more preferably 30° or greater, and more preferably 40° or greater. Of course, each liquid-repellent region is required to have adequate liquid-repellent properties. However, if the contact angle in this region relative to the liquid is unduly small, the region cannot exhibit sufficient liquid-repellent properties, as such the luminescent-layer-forming coating liquid or the like may tend to be attached to such liquid-repellent regions.

In each lyophilic region, it is preferred that the contact angle relative to the liquid having the surface tension equivalent to that of the luminescent-layer-forming coating liquid is 20° or less, more preferably 15° or less, and more preferably 10° or less. If the contact angle in this region relative to the liquid is unduly great, the luminescent-layer-forming coating liquid or the like may be unlikely to be wet and spread over the surface of the region, leading to occurrence of defects of the luminescent layer.

The contact angle relative to the liquid can be obtained, by first measuring contact angles relative to liquids having various surface tension values by using a contact angle meter (e.g., produced by KYOWA-KAIMEN-KAGAKU Co. Ltd., CA-Z type) (at 30 seconds after forming each liquid drop by using a micro-syringe), and then plotting the results of measurement on a graph. For this measurement, wettability-index reference liquids, produce by JUNSEI-KAGAKU Co. Ltd., can be used as the liquids having various surface tension values.

In the case in which the wettability changing layer contains fluorine, when the content of fluorine in each liquid-repellent region is designated by 100 as a reference value, the content of fluorine in each lyophilic regions is preferably 50 or less, more preferably 20 or less, and more preferably 10 or less. It is noted that this ratio is based on the weight. With such a ratio of the fluorine content, a significantly greater difference in the wettability can be provided between the liquid-repellent regions and the lyophilic regions. Accordingly, as described above, upon forming the luminescent layer on the wettability changing layer, the luminescent layer can be formed accurately only on each lyophilic regions with a significantly less fluorine content, as such obtaining a highly precise fine pattern of the luminescent layer.

For the measurement of the fluorine content, various methods, which are generally known and commonly used, can be employed. For instance, a method that can measure quantitatively the amount of fluorine contained in the surface, such as the X-ray photoelectron spectroscopy (also referred to as the ESCA (Electron Spectroscopy for Chemical Analysis)), fluorescent X-ray spectrometry, mass-spectrometry and the like, can be used.

### 3. Luminescent-Layer-Forming Step

In the luminescent-layer-forming step of this embodiment, the luminescent-layer-forming coating liquid containing the quantum dots, around each of which the ligands are attached, is coated on each lyophilic regions, thereby forming the luminescent layer.

The luminescent-layer-forming step of this embodiment may be a step (i.e., a third aspect) of forming a single luminescent layer, by using the luminescent-layer-forming coating liquid containing the quantum dots, around each of which the ligands are attached; or may be another step (i.e., a fourth step) of forming the single luminescent layer, by using the luminescent-layer-forming coating liquid containing the quantum dots, around each of which the ligands are attached, and at least one of a positive-hole transporting material and an electron transporting material; or otherwise may be still another step (i.e., a fifth step) of collectively forming the luminescent layer and a positive-hole transporting layer, by using the luminescent-layer-forming coating liquid containing the quantum dots, around each of which the ligands are attached, and the positive-hole transporting material. Hereinafter, these aspects will be discussed, respectively.

### (1) Third Aspect

In the luminescent-layer-forming step of this aspect, the luminescent-layer-forming coating liquid containing the quantum dots, around each of which the ligands are attached, is coated on the lyophilic regions, so as to form the single luminescent layer. Hereinafter, a method for forming the luminescent-layer-forming coating liquid and luminescent layer will be described, respectively.

### (i) Luminescent-Layer-Forming Coating Liquid

The luminescent-layer-forming coating liquid employed for this aspect contains the quantum dots, around each of which the ligands are attached, and is usually used, with the quantum dots, around each of which the ligands are attached, being dispersed therein. Hereinafter, each component of the luminescent-layer-forming coating liquid will be described.

### (Quantum Dots)

As the quantum dots used in this aspect, any suitable material can be used, provided that it can adequately emit fluorescence or phosphorescence. Especially, the quantum dots, each containing or consisting of the so-called compound semiconductor, are preferred. As the compound semiconductor, for example, compounds of the group IV, compounds of the groups I-VII, compounds of the groups II-VI, compounds of the groups II-V, compounds of the groups III-VI, compounds of the groups III-V, compounds of the groups IV-VI, compounds of the groups I-III-VI, compounds of the groups II-IV-VI, compounds of the groups II-IV-V and the like can be mentioned. Specifically, ZnS, ZnSe, ZnTe, CdS, CdSe, CdTe, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbS, PbSe, PbTe, and any suitable blend thereof can be mentioned. Among them, CdSe is preferred, in view of applicability, practicability and optical properties.

Each quantum dot may be composed of only a core portion formed from semiconductor fine particles, or may be composed of such a core portion and a shell portion covering the core portion and formed from a material having the energy band gap greater than that of the semiconductor fine particles. In particular, the quantum dots, each composed of both of the core portion and shell portion, are preferred. Namely, each quantum dot has a core-shell structure, and is referred to as a “core-shell type quantum dot.” This is because such a core-shell structure can securely enhance the stability of each quantum dot.

As the semiconductor particles used for each core portion, fine particles of the compound semiconductor as described above are preferred.

As the material used for the shell portion, any suitable material can be used, provided that the energy band gap thereof is greater than that of the semiconductor fine particles. However, similar to the semiconductor fine particles, it is preferred that the material for the shell portion is also composed of or consists of such a compound semiconductor. In this case, the compound semiconductor used for each shell portion may be the same as or different from the compound semiconductor used for each core portion.

As the core-shell type quantum dots, CdSe/CdS, CdSe/ZnS, CdTe/CdS, InP/ZnS, GaP/ZnS, Si/ZnS, InN/GaN, InP/CdSSe, InP/ZnSeTe, GaInP/ZnSe, GaInP/ZnS, Si/AIP, InP/ZnSTe, GaInP/ZnSTe, GaInP/ZnSSe and the like can be mentioned. Among them, CdSe/ZnS is preferred, in view of the applicability, practicability and optical properties.

As a shape of each quantum dot, for example, a spherical shape, a rod-like shape, a disc-like shape and the like can be mentioned.

It is noted that the shape of each quantum dot can be checked by using a transmission electron microscope (TEM).

Preferably, the particle size of each quantum dot is 20 nm or less, for example, within a range of from lnm to 15 nm, and more preferably 1 nm to 10 nm. If the particle size of each quantum dot is unduly large, an adequate quantum-dot-size effect cannot be obtained.

Generally, the emission spectrum of the quantum dots varies with the particle size thereof. Therefore, the particle size of the quantum dots should be selected appropriately, corresponding to an aimed color. For instance, in the case of the core-shell type quantum dots consisting of CdSe/ZnS, the emission spectrum will be shifted toward a longer wavelength side with increase of the particle size. More specifically, such quantum dots will create a red color when the particle size is 5.2 nm, while exhibiting a blue color when the particle size is 1.9 nm.

It is preferred the distribution of the particle size of the quantum dots is in a relatively narrow range.

It is noted that the particle size of the quantum dots can be grasped, by using the transmission electron microscope (TEM), a powder X-ray diffraction (XRD) pattern or UV/Vis absorption spectrum.

Preferably, the content of the quantum dots, around each of which the ligands are attached, and which are contained in the luminescent-layer-forming coating liquid, is within a range of from 50% to 100% by weight, and more preferably within a range of from 60% to 100% by weight, on the basis of 100% by weight of the total solid content in the luminescent-layer-forming coating liquid. If the content of the quantum dots is unduly low, adequate emission cannot be obtained. Meanwhile, an excessively high content of the quantum dots will make it significantly difficult to appropriately form the luminescent layer.

As a method for synthesizing the quantum dots, those disclosed in TOKUHYOU No. 2005-522005, KOHO, TOKUHYOU No. 2006-520077, KOHO, JP2007-21670A, etc. are known.

As required, the ligans attached around the surface of each quantum dot can be exchanged by other ligands. For instance, by mixing the quantum dots, each having TOPO or the like attached around the surface thereof, with a large quantity of a proper silane coupling agent, such TOPO or the like can be replaced by the silane coupling agent. Preferably, the temperature upon such replacement of the ligands is set around a room temperature.

As a method for replacing the ligands, those disclosed in JP2007-21670A are known.

As commercially available quantum dots, around each of which the ligands, such as TOPO or the like, are attached, for example, “Evidot” consisting of fluorescent semiconductor nano-crystals and produced by Evident TECHNOLOGIES Co. Ltd. can be mentioned.

### (Ligands)

As the ligands used in this aspect, those generally known and commonly used for the quantum dots can be used. For instance, alkylphosphine, such as tri-n-octylphosphine (TOP), alkylphosphine oxide, such as tri-n-octylphosphine oxide (TOPO), alkylphosphonic acid, alkylphosphinic acid, such as tris-hydroxypropylphosphine (tHP), pyridine, furan, hexadecylamine, and the like can be mentioned.

In this aspect, the silane coupling agent can be used as the ligands. In this case, the silane coupling agent is attached to each quantum dot via a coordinate covalent bond. Namely, in the case in which each quantum dot is composed of the compound semiconductor, an —OH group of each Si—OH group of the silane coupling agent that has been hydrolyzed can coordinate with the quantum dot, because a surface of an inorganic material is generally liquid-philic.

Among the ligands described above, the silane coupling agent is preferred. Namely, by using the luminescent-layer-forming coating liquid containing the silane coupling agent, the luminescent layer can be cured adequately. Thus, the stability of the quantum dots in the luminescent layer can be enhanced, leading to improvement of the life properties. Besides, thermo-stability of the luminescent layer (i.e., Tg: glass-transition temperature) can also be improved. In addition, the molecular design for such a silane coupling agent can be carried out with ease. Therefore, by using such a silane coupling agent having functional groups for exhibiting a variety of functionality, the life properties can be further ameliorated.

Furthermore, in the case in which the organopolysiloxane is contained in the wettability changing layer and in which the silane coupling agent is used as the ligands, the adhesion properties, between the first electrode layer, the wettability changing layer and the luminescent layer, can be significantly enhanced.

Additionally, in the case in which the luminescent layer is cured, a problem, such as solution of the luminescent layer into a solvent contained in a coating liquid for forming a positive-hole injecting and transporting layer or electron injecting and transporting layer or the like, can be avoided or eliminated, upon forming the positive-hole injecting and transporting layer or electron injecting and transporting layer on the luminescent layer by using the coating liquid. Therefore, the positive-hole injecting and transporting layer and/or electron injecting and transporting layer can be stably laminated on the luminescent layer.

As the silane coupling agent used in this aspect, any suitable agent can be used, provided that it can coordinate with the quantum dots so as to stabilize them. For example, (1) chloro- or alkoxy-silanes or the like and (2) reactive silicones can be mentioned.

As the chloro- or alkoxy-silanes in the above case (1), a silicon compound of the following general formula is preferred:

YnSiX(4−n),

in which Y is an alkyl group, fluoroalkyl group, vinyl group, amino group, phenyl group or epoxy group, X is an alkoxyl group, acetyl group or halogen, and n is an integer of from 0 to 3. Such silicon compounds may be used alone or in a combination of two or more thereof.

In the silicon compound expressed by the above formula, X designates a terminal end, i.e., a coordinating portion that is coupled with each quantum dot via the coordinate covalent bond. It should be appreciated that such a terminal end can be used as a site, by which a condensation reaction can be performed. Thus, such a terminal end can serve to couple the quantum dots, each having the silane coupling agent attached around the surface thereof, with one another, render the luminescent layer insoluble to the solvent, and improve the adhesion properties between the luminescent layer and the wettability changing layer.

Preferably, the alkoxyl group designated by X is a methoxy group, ethoxy group, propoxy group or butoxy group.

In the silicon compound expressed by the above formula, Y designates a functional site.

For instance, in the case in which Y is an alkyl group, this site designated by Y serves as a spacer provided between the quantum dots and adapted for controlling the solubility. Alternatively, in the case in which Y is a fluoroalkyl group, this site serves as the spacer provided between the quantum dots and adapted for exhibiting the liquid-repellent properties. Alternatively, in the case in which Y is a vinyl group, this site serves as the spacer provided between the quantum dots and adapted for constituting a n conjugated system. Alternatively, in the case in which Y is an amino group, this site serves as the spacer provided between the quantum dots and adapted for exhibiting the liquid-philic properties. Alternatively, in the case in which Y is a phenyl group, this site serves as the spacer provided between the quantum dots and adapted for the liquid-repellent properties. Alternatively, in the case in which Y is an epoxy group, this site serves as the spacer provided between the quantum dots and adapted for controlling curing properties.

Preferably, the number of carbon atoms of the group designated by Y is within a range of from 1 to 20.

As the silicon compound expressed by the above general formula, for example, those described in JP2000-249821A can be used.

As the chloro- or alkoxy-silanes in the above case (1), a silicon compound of the following general formula is also preferred:

YnSiX(4−n),

in which in which Y is a functional group, which can exhibit positive-hole transporting properties, wherein each positive hole can be coupled, directly or via a vinyl group or phenyl group, with this functional group, or another functional group, which can exhibit electron transporting properties, wherein each electron can be coupled, directly or via a vinyl group or phenyl group, with this functional group, or still another functional group, which can exhibit both of the positive-hole transporting properties and electron transporting properties, wherein each positive hole or electron can be coupled, directly or via a vinyl group or phenyl group, with this functional group, X designates an alkoxyl group, acetyl group or halogen, and n is an integer of 0 to 3. Such silicon compounds may be used alone or in a combination of two or more thereof.

In the silicon compound expressed by the above formula, X designates a terminal end, i.e., a coordinating portion that is coupled with each quantum dot via the coordinate covalent bond. It should be appreciated that such a terminal end can be used as a site, by which a condensation reaction can be performed. Thus, such a terminal end can be used to couple the quantum dots having the silane coupling agent attached around the surface thereof, with one another, render the luminescent layer insoluble to the solvent, and improve the adhesion properties between the luminescent layer and the wettability changing layer.

Preferably, the alkoxyl group designated by X is a methoxy group, ethoxy group, propoxy group or butoxy group.

In the silicon compound expressed by the above formula, Y designates a functional site.

For instance, in the case in which Y is such a functional group that can exhibit the positive-hole transporting properties, wherein each positive hole can be coupled, directly or via a vinyl group or phenyl group, with this functional group, this site designated by Y can serve as a spacer provided between the quantum dots and adapted for exhibiting the positive-hole transporting properties. Alternatively, in the case in which Y is such a functional group that can exhibit the electron transporting properties, wherein each electron can be coupled, directly or via a vinyl group or phenyl group, with this functional group, this site Y can serve as the spacer provided between the quantum dots and adapted for exhibiting the electron transporting properties. Alternatively, in the case in which Y is such a functional group that can exhibit both of the positive-hole transporting properties and electron transporting properties, wherein each positive hole or electron can be coupled, directly or via a vinyl group or phenyl group, with this functional group, this site Y can serve as the spacer provided between the quantum dots and adapted for exhibiting both of the positive-hole transporting properties and electron transporting properties.

In the case in which Y is the functional group that can exhibit the positive-hole transporting properties, wherein each positive hole can be coupled, directly or via a vinyl group or phenyl group, with this functional group, it is preferred that Y is such a functional group that can exhibit the positive-hole transporting properties, wherein each positive hole can be coupled, via a vinyl group or phenyl group, with this functional group. This is because such a vinyl group or phenyl group can constitute the n conjugated system.

As the functional group that can exhibit the positive-hole transporting properties, aromatic amine groups having one or more nitrogen atoms, or substituted or non-substituted aryl groups having 6 to 16 carbon atoms can be mentioned.

As the aromatic amine group having one or more nitrogen atoms, a tertiary amine group having one or more nitrogen atoms is preferred. More specifically, triphenylamins, such as N,N′-bis(naphthalene-1-yl)-N,N′-bis(phenyl)-benzidine (α-NPD), 4,4,4-tris(3-methylphenylamino)triphenylamine (MTDATA) or the like, can be mentioned. As the triphenylamine, a chemical structure expressed by the following chemical formula can be mentioned.

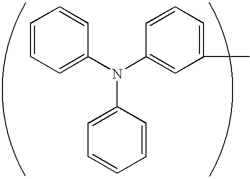

As the aryl group having 6 to 16 carbon atoms, a phenyl group, a naphthyl group, a tolyl group, a xylyl group, an anthryl group, a phenanthryl group, a biphenyl group, a naphthacenyl group, a pentacenyl group and the like can be mentioned.

Alternatively, in the case in which Y is the functional group that can exhibit the electron transporting properties, wherein each electron can be coupled, directly or via a vinyl group or phenyl group, with this functional group, it is preferred that Y is such a functional group that can exhibit the electron transporting properties, wherein each electron can be coupled, via a vinyl group or phenyl group, with this functional group. This is because such a vinyl group or phenyl group can constitute the n conjugated system.

As the functional group that can exhibit the electron transporting properties, for example, phenanthroline, triazole, oxadiazole, alumiquinolinole or the like can be mentioned. More specifically, basocuproine (BCP), basophenanthroline (Bpehn), tris-(8-hydroxylinolato)-aluminum (Alq3) and the like can be mentioned. As the oxadiazole and triazole, those as respectively expressed by the following structural formulae can be mentioned.

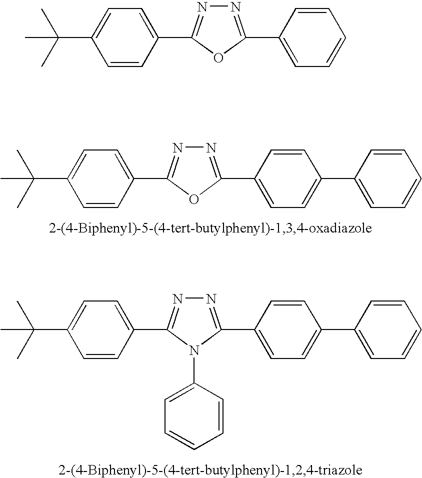

Additionally, as the functional group that can exhibit the electron transporting properties, substituted or non-substituted aryl groups having 6 to 16 carbon atoms can be mentioned. Such aryl groups having 6 to 16 carbon atoms are the same as those described above.

Alternatively, in the case in which Y is the functional group that can exhibit both of the positive-hole transporting properties and electron transporting properties, wherein each positive hole or electron can be coupled, directly or via a vinyl group or phenyl group, with this functional group, it is preferred that Y is such a functional group that can exhibit both of the positive-hole transporting properties and electron transporting properties, wherein each positive hole or electron can be coupled, via a vinyl group or phenyl group, with this functional group. This is because such a vinyl group or phenyl group can constitute the n conjugated system.

As the functional group that can exhibit both of the positive-hole transporting properties and electron transporting properties, for example, distyryl allene, poly-aromatic compounds, aromatic condensed-ring compounds, carbazole, heterocyclic compounds or the like can be mentioned. More specifically, 4,4′-bis(2,2-diphenyl-ethen-1-yl)diphenyl (DPVBi), 4,4′-bis(carbazol-9-yl)biphenyl (CBP), 4,4″-di(N-carbazolyl)-2′,3′,5′,6′-tetraphenyl-p-terphenyl (CzTT), 1,3-bis(carbazole-9-yl)-benzene (m-CP), 9,10-di(naphtha-2-yl)anthracene (DNA) and the like, as respectively expressed by the following formulae, can be mentioned.

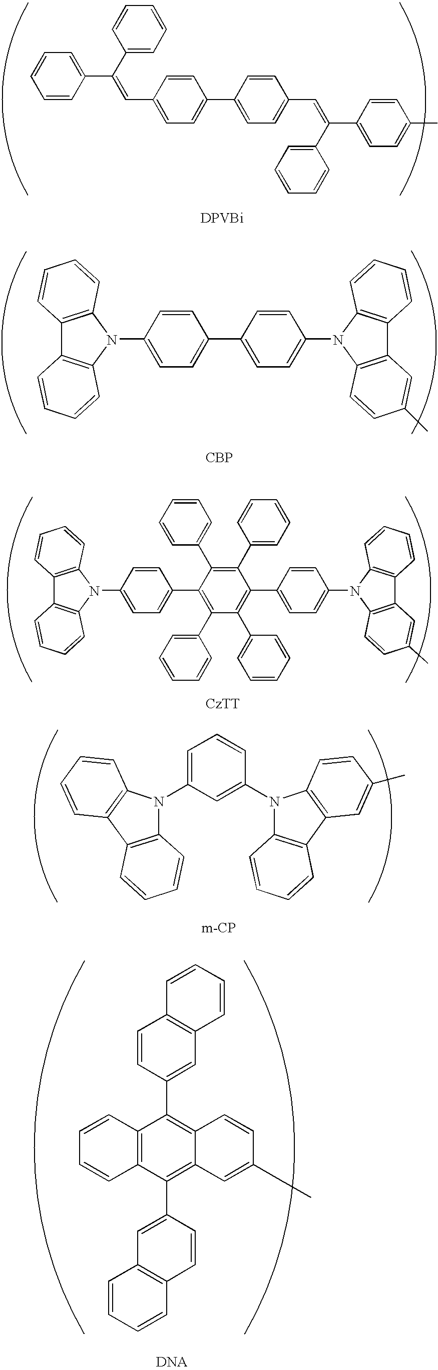

Additionally, those expressed by the following chemical formula can also be mentioned.

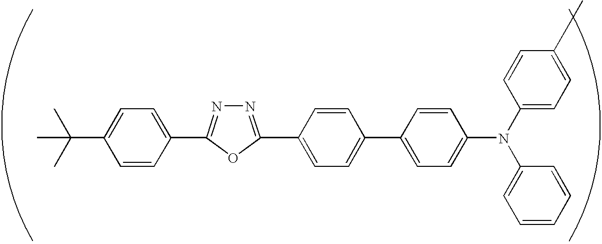

Additionally, as the functional group that can exhibit both of the positive-hole transporting properties and electron transporting properties, substituted or non-substituted aryl groups having 6 to 16 carbon atoms can be mentioned. It is noted that such aryl groups having 6 to 16 carbon atoms are the same as those described above.

As the reactive silicone in the above case (2), compounds having a basic skeleton expressed by the following chemical formula can be mentioned.

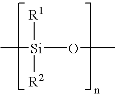

In the above chemical formula, n is an integer of 2 or greater, R¹, R² are independently a substituted or non-substituted alkyl group, alkenyl group, aryl group or cyanoalkyl group, each having 1 to 10 carbon atoms, with vinyl groups, phenyl groups and/or halogenated phenyl groups included in the above skeleton at a molar ratio of 40% or less. Preferably, R¹, R² are both methyl groups, wherein it is preferred that such methyl groups are included in the above skeleton at a molar ratio of 60% or greater. In addition, this skeleton includes at least one reactive group, such as a hydroxyl group or the like, in its molecular chain, e.g., at its terminal ends and/or side chains.

The silane coupling agent described above may have the electron transporting properties. In order to prepare the silane coupling agent having the electron transporting properties, the functional site Y of the above the general formula in the case (1) may be such a functional group that can exhibit the positive-hole transporting properties, wherein each positive hole can be coupled, directly or via a vinyl group or phenyl group, with this functional group, or may be such a functional group that can exhibit the electron transporting properties, wherein each electron can be coupled, directly or via a vinyl group or phenyl group, with this functional group, or otherwise may be such a functional group that can exhibit both of the positive-hole transporting properties and electron transporting properties, wherein each positive hole or electron can be coupled, directly or via a vinyl group or phenyl group, with this functional group.

The luminescent-layer-forming coating liquid may contain a relatively stable organosilicone compound (e.g., dimethylpolysiloxane) that causes no cross-linking reaction.

### (Solvent)

As a solvent that can be used for preparing the luminescent-layer-forming coating liquid employed in this aspect, any suitable solvent can be selected, provided that it can be adequately mixed with the quantum dots, around each of which the ligands are attached. Especially, in the case in which the silane coupling agent is used as the ligands, it is preferable to select and use such an agent that causes no cloudiness or the like negative phenomenon. As such a solvent, for example, aromatic-hydrocarbon-type solvents, such as xylene, toluene, cyclohexylbenzene, dihydrobenzofuran, trimethylbenzene, tetramethylbenzen and the like; aromatic-heterocyclic-type solvents, such as pyridine, pyrazine, furan, pyrrole, thiophene, methylpyrrolidone and the like; and aliphatic-hydrocarbon-type solvents, such as hexane, pentane, heptane, cyclohexane and the like, can be mentioned. Such solvents may be used alone or as a mixture thereof.

### (Other Materials)

To the luminescent-layer-forming coating liquid used in this aspect, various additives can be added. For instance, in the case of forming the luminescent layer by the injection method, a proper surfactant or the like additive may be added for the purpose of enhancing discharging properties.

Alternatively or additionally, in the case in which the luminescent layers respectively adapted for displaying the three primary colors of light, i.e., red, green and blue colors, the luminescent-layer-forming coating liquids are used, respectively, corresponding to each of the red, green and blue colors of light. As described above, the particle size of the quantum dots is selected for each color, because the quantum dots will exhibit different emission spectra, depending on the particle size thereof.

### (ii) Method for the Luminescent Layer

In this aspect, the luminescent layer is formed by coating the luminescent-layer-forming coating liquid on each lyophilic regions.

As a method for coating the luminescent-layer-forming coating liquid, for example, the spin coating, casting, dip coating, bar coating, blade coating, roll coating, spray coating, flexographic printing, gravure printing, offset printing, screen printing, or discharge method with a dispenser or by injection can be mentioned. Above all, the discharge method, flexographic printing or gravure printing is preferred. In particular, the discharge method is preferred. Furthermore, the injection method is more preferable. Namely, this method can form a highly precise pattern by utilizing the wettability changing pattern.

After the coating of the luminescent-layer-forming coating liquid, the resultant coated film may be dried. As a method for drying the coated film, any suitable method can be used, provided that it can form a substantially uniform luminescent layer. For instance, a hot plate, infrared heater, oven or the like can be used.

In particular, in the case in which the silane coupling agent is used as the ligands, it is preferable to cure the coated film after the luminescent-layer-forming coating liquid is coated. Such a drying process can promote the condensation reaction of the hydrolyzed silane coupling agent, thereby to adequately cure the luminescent layer.

Any suitable thickness of the luminescent layer can be applied, provided that it can provide a suitable space in which the electrons and positive holes can be recombined together to make emission. For instance, the thickness can be set within a range of from 1 nm to 500 nm.

### (2) Fourth Aspect

In the luminescent-layer-forming step of this aspect, the luminescent-layer-forming coating liquid, containing the quantum dots, around each of which the ligands are attached, and at least either one of the positive-hole transporting material and electron transporting material, is coated on each lyophilic regions so as to form a single luminescent layer.

In this aspect, a function for the emission as well as a function for transporting the positive holes or electrons can be provided to the luminescent layer. This can facilitate the steps required for manufacturing the EL element, as well as can render the transportation of electrons into the luminescent layer and energy transfer of the excitons produced by the recombination between the positive holes and electrons more efficient. Therefore, the life properties of the EL element can be securely enhanced.

It is noted that the method of forming the luminescent layer is the same as that discussed in the above third aspect. Therefore, the description on this method is now omitted. Herein after, the luminescent-layer-forming coating liquid used in this aspect will be described.

### (i) Luminescent-Layer-Forming Coating Liquid

The luminescent-layer-forming coating liquid used in this aspect contains the quantum dots, around each of which the ligands are attached, and at least either one of the positive-hole transporting material and electron transporting material. Usually, in this liquid, the quantum dots, around each of which the ligands are attached, and at least either one of the positive-hole transporting material and electron transporting material are dispersed and/or solved in the solvent.

This luminescent-layer-forming coating liquid may be prepared as one that contains the quantum dots, around each of which the ligands are attached, and at least either one of the positive-hole transporting material and electron transporting material. Preferably, the luminescent-layer-forming coating liquid used in this aspect contains the quantum dots, around each of which the ligands are attached, and both of the positive-hole transporting material and electron transporting material. Namely, the luminescent layer formed with the latter luminescent-layer-forming coating liquid can achieve more efficient transportation of the electrons toward the quantum dots as well as more efficient energy transfer of the excitons produced by the recombination between the positive holes and the electrons.

Since the ligands are the same as those described in the third aspect, the explanation on this material is now omitted. Hereinafter, another example of the luminescent-layer-forming coating liquid will be discussed.

### (Quantum Dots)

Preferably, the content of the quantum dots, around each of which the ligands are attached and which are contained in the luminescent-layer-forming coating liquid, is within a range of from 10% to 90% by weight, and more preferably within a range of from 30% to 70% by weight, on the basis of 100% by weight of the total solid content in the luminescent-layer-forming coating liquid. If the content of the quantum dots is unduly low, adequate emission cannot be achieved. Meanwhile, if the content is excessively high, the formation of the luminescent layer will be considerably difficult. Furthermore, such an excessively high content of the quantum dots may substantially deteriorate the function for transporting the positive-holes and/or electrons into the luminescent layer.

Since other features of the quantum dots are the same as those discussed in the third aspect, the description on these points is now omitted.

### (Positive-Hole Transporting Material)

As the positive-hole transporting material used in this aspect, for example, arylamine derivatives, anthracene derivatives, carbazole derivatives, thiophene derivatives, fluorene derivatives, distyrylbenzene derivatives, spiro compounds and the like can be mentioned. More specifically, 4,4′-bis[N-(1-naphthyl)-N-phenyl-amino]-biphenyl (α-NPD), N,N′-bis-(3-methylphenyl)-N,N′-bis-(phenyl)-benzidine (TPD), 4,4′,4″-tris[N-(3-mehylphenyl)-N-phenyl-amino]-triphenylamine (MTDATA), 9,10-di-2-naphthylanthracene (DNA), 4,4-N,N′-dicarbazole-biphenyl (CBP), 1,4-bis(2,2-diphenylvinyl)benzne (DPVBi) and the like can be mentioned. Such materials may be used alone or as a mixture of two or more thereof.

In the case in which the luminescent-layer-forming coating liquid contains the quantum dots, around each of which the ligands are attached, and the positive-hole transporting material, it is preferred that a mixing ratio, between the quantum dots, around each of which the ligands are attached, and the positive-hole transporting material, i.e., (the quantum dots, around each of which the ligands are attached):(the positive-hole transporting material), is approximately 1:0.1 to 2. If the ratio of the quantum dots is too small, adequate emission cannot be obtained. Meanwhile, if the ratio of the quantum dots is excessively large, the formation of the luminescent layer will be considerably difficult. Furthermore, such an excessively large ratio of the quantum dots may substantially deteriorate the function for transporting the positive-holes into the luminescent layer.

### (Electron Transporting Material)

As the electron transporting material used in this aspect, for example, phenanthroline derivatives, such as basocuproine (BCP), basophenanthroline (Bpehn) and the like; triazole derivatives; oxadiazole derivatives; and alumiquinolinole complexes, such as tris(8-quinolinole)-aluminum complexes (Alq3) and the like; can be mentioned.

In the case in which the luminescent-layer-forming coating liquid contains the quantum dots, around each of which the ligands are attached, and the electron transporting material, it is preferred that a mixing ratio, between the quantum dots, around each of which the ligands are attached, and the electron transporting material, i.e., (the quantum dots, around each of which the ligands are attached):(the electron transporting material), is approximately 1:0.1 to 2. If the ratio of the quantum dots is too small, adequate emission cannot be obtained. Meanwhile, if the ratio of the quantum dots is excessively large, the formation of the luminescent layer will be significantly difficult. Besides, such an excessively large ratio of the quantum dots may substantially deteriorate the function for transporting electrons into the luminescent layer.

Furthermore, in the case in which the luminescent-layer-forming coating liquid contains the quantum dots, around each of which the ligands are arranged, and both of the positive-hole transporting material and electron transporting material, the ratio, between the quantum dots, around each of which the ligands are attached, the positive-hole transporting material and the electron transporting material, i.e., (the quantum dots, around each of which the ligands are attached):(the positive-hole transporting material):(the electron transporting material), is approximately 1:0.1 to 2:0.1 to 2. If the ratio of the quantum dots is too small, adequate emission cannot be obtained. Meanwhile, if the ratio of the quantum dots is excessively large, the formation of the luminescent layer will be significantly difficult. Furthermore, such an excessively large ratio of the quantum dots may substantially deteriorate the function for transporting the positive-holes and/or electrons into the luminescent layer.

### (Solvent)

As the solvent that can be used in the luminescent-layer-forming coating liquid employed in this aspect, a non-polar solvent is preferred. For example, aromatic-hydrocarbon-type solvents, such as xylene, toluene, cyclohexylbenzene, dihydrobenzofuran, trimethylbenzene, tetramethylbenzene and the like; aromatic-heterocyclic-type solvents, such as pyridine, pyrazine, furan, pyrrole, thiophene, methylpyrrolidone and the like; and aliphatic-hydrocarbon-type solvents, such as hexane, pentane, heptane, cyclohexane and the like, can be mentioned. Such solvents may be used alone or as a mixture thereof.

### (Other Materials)

The luminescent-layer-forming coating liquid can be prepared, by first dissolving at least either one of the positive-hole transporting material and electron transporting material into the solvent, and then dispersing the quantum dots, around each of which the ligands are attached, into the solvent.

Since other features of the luminescent-layer-forming coating liquid are the same as those discussed in the third aspect, the description on these points is now omitted.

It is noted that the luminescent layer formed in the luminescent-layer-forming step of this aspect is described in more detail in TOKUHYOU No.2005-522005, KOHO.

### (Fifth Aspect)

The luminescent-layer-forming step of this aspect uses the luminescent-layer-forming coating liquid containing the quantum dots, around each of which the ligands are attached, together with the positive-hole transporting material and solvent. In this step, the luminescent-layer-forming coating liquid is first coated on the wettability changing layer so as to form a film thereon. Thereafter, the solvent contained in the coated film is removed, while the positive-hole transporting material is transferred toward the first electrode layer. During this operation, the quantum dots, around each of which the ligands are attached, are respectively moved toward an uppermost face of the coated film while being separated from the positive-hole transporting material. In this way, the positive-hole transporting layer and luminescent layer can be formed collectively.

In this aspect, the luminescent-layer-forming coating liquid containing the quantum dots, around each of which the ligands are attached, together with the positive-hole transporting material and solvent is first coated on the substrate having a photoresist layer formed thereon into a pattern-like shape, and then subjected to phase separation (i.e., vertical phase separation) such that the quantum dots, around each of which the ligands are arranged, and the positive-hole transporting material are separated from each other. As a result, as shown in FIG. 3, the positive-hole transporting layer 9 and luminescent layer 7 can be formed simultaneously. In this case, the positive-hole transporting layer 9 and luminescent layer 7 are separated into two phases, while a phase separation interface 23 is created between the positive-hole transporting layer 9 and the luminescent layer 7.

In the case in which the phase separation interface is created between the positive-hole transporting layer and the luminescent layer, in a macroscopic view as exemplarily shown in FIG. 3, the phase separation interface 23 will take a position substantially parallel with the first electrode 2, wherein the luminescent layer 7 and positive-hole transporting layer 9 penetrate each other, as shown in FIG. 4. Thus, the phase separation interface 23 can be considered as a concavo-convex face formed between the two layers 7, 9. Consequently, a significantly wide contact area can be obtained between the positive-hole transporting layer and the luminescent layer, thereby increasing a site or space for the recombination between the electrons and the positive holes. Besides, this recombination site is present in a position spaced away from the first electrode layer, thus providing a relatively wide emission site (i.e., the number of molecules that can contribute to the emission can be increased). Accordingly, further enhancement of the efficiency of emission as well as elongation of the life of the EL element can be attempted by utilizing this aspect.

In addition, since the interface between the positive-hole transporting layer and the luminescent layer is not flat (or uniform) but has a concavo-convex shape, simultaneous excitation due to sudden recombination of all of the positive holes and electrons can be avoided even when the driving voltage is considerably elevated, thereby preventing a sudden rise of intensity of the emission. Therefore, the luminance can be elevated moderately, corresponding to the driving voltage applied, thus facilitating control for the luminance during the emission as well as control for gradation during a lower luminance operation. In addition, this aspect can eliminate a need for providing a complicated peripheral circuit for finely controlling the driving voltage.

Hereinafter, the method for preparing the luminescent-layer-forming coating liquid and forming the luminescent layer will be described.

### (i) Luminescent-Layer-Forming Coating Liquid

The luminescent-layer-forming coating liquid used in this aspect contains the quantum dots, around each of which the ligands are attached, and the positive-hole transporting material.

It is noted that the quantum dots and ligands are the same as those used in the third aspect, and that the positive-hole transporting material and solvent are the same as those used in the fourth aspect. Therefore, the explanation on these materials is now omitted.

In this aspect, it is preferred that the content of the quantum dots, around each of which the ligands are attached and which is contained in the luminescent-layer-forming coating liquid, is within a range of from 10% to 90% by weight, and more preferably within a range of from 30% to 70% by weight, on the basis of 100% by weight of the total solid content in the luminescent-layer-forming coating liquid. If the content of the quantum dots is unduly low, adequate emission cannot be obtained. Meanwhile, if the content is excessively high, the phase separation, between the quantum dots, around each of which the ligands are attached, and the positive-hole transporting material, will be significantly difficult.

Additionally, in this luminescent-layer-forming coating liquid, it is preferred that the mixing ratio, between the quantum dots, around each of which the ligands are attached, and the positive-hole transporting material, i.e., (the quantum dots, around each of which the ligands are attached):(the positive-hole transporting material), is approximately 1:0.1 to 2. If the ratio of the quantum dots is too small, adequate emission cannot be obtained. Meanwhile, if the ratio of the quantum dots is excessively large, the phase separation, between the quantum dots, around each of which the ligands are attached, and the positive-hole transporting material, will be significantly difficult.

The luminescent-layer-forming coating liquid used in this aspect can be prepared by first dissolving the positive-hole transporting material into the solvent and then dispersing the quantum dots, around each of which the ligands are attached, into the resultant solution.

It is noted that other features of the luminescent-layer-forming coating liquid are the same as those in the third aspect.

### (ii) Method for Forming the Luminescent Layer

In this aspect, the luminescent-layer-forming coating liquid is first coated on the wettatility changing layer so as to form a film thereon. Thereafter, the solvent contained in the coated film is removed, while the positive-hole transporting material is transferred toward the first electrode layer. During this operation, the quantum dots, around each of which the ligands are attached, are respectively moved toward the uppermost face of the coated film while being separated from the positive-hole transporting material. In this way, the positive-hole transporting layer and luminescent layer can be formed simultaneously.

It is noted that this coating method of the luminescent-layer-forming coating liquid is the same as that discussed in the third aspect, the description on this method is now omitted.

As described above, after the coated film is formed by coating the luminescent-layer-forming coating liquid onto the substrate, the solvent is removed from the film. Once the solvent is removed, in the coated film, as exemplarily shown in FIG. 4, the positive-hole transporting material (not shown) is positioned near the first electrode 2, while the quantum dots 22, around each of which the ligands (not shown) are attached, are located around the uppermost face of the coated film. Thus, the phases of these two components are separated in the vertical direction from each other, while the coated film is solidified. In this way, the positive-hole transporting layer 9 and luminescent layer 7 can be formed collectively at a time. Namely, the positive-hole transporting layer and luminescent layer can be formed simultaneously with the phase separation.

In this case, the phase separation between the positive-hole transporting material and the quantum dots, around each of which the ligands are attached, can be controlled by appropriately setting at least one of the following conditions: the kind of the solvent; weight-average molecular weight of the positive-hole transporting material; content of the positive-hole transporting material in the luminescent-layer-forming coating liquid; contents of the quantum dots and ligands in the luminescent-layer-forming coating liquid; rate of removing the solvent; atmosphere upon removing the solvent and surface condition of the base layer on which the luminescent-layer-forming coating liquid is coated.

For example, the atmosphere upon removing the solvent may contain vapor of a polar solvent. In this way, the quantum dots, around each of which the ligands are attached, can be gathered more securely around the uppermost face of the coated film. As the polar solvent, for example, water, and proper alcohol, such as methanol, ethanol and isopropanol, can be mentioned.

It is noted that the coated film may be dried after the coating of the luminescent-layer-forming coating liquid. Since the drying method for the coating film is the same as that discussed in the third aspect, the explanation on this method is now omitted.

Especially, in the case of using the silane coupling agent as the ligands, it is preferred that the coated film is cured after the coating of the luminescent-layer-forming coating liquid. With such a drying process, the condensation reaction of the hydrolyzed silane coupling agent can be further promoted, as such adequately curing the luminescent layer.

In regard to the thickness of the luminescent layer, any suitable thickness can be employed, provided that it allows the electrons and positive holes to be recombined together and can exhibit an adequate function for the emission. For example, this thickness is approximately within a range of from 1 nm to 500 nm.

### 4. Positive-Hole-Injecting-and-Transporting-Layer-Forming Step

In this aspect, a positive-hole-injecting-and-transporting-layer-forming step for forming the positive-hole injecting and transporting layer on each lyophilic regions may be performed, prior to the luminescent-layer-forming step. With the provision of such a positive-hole injecting and transporting layer, the injection of the positive holes into the luminescent layer can be stabilized, as well as the transportation of the positive holes can be smoothly performed. As such, the efficiency of the emission can be enhanced.

In the case of performing the positive-hole-injecting-and-transporting-layer-forming step and luminescent-layer-forming step in this order, the positive-hole injecting and transporting layer is first formed only on each lyophilic regions. In this manner, the surface of the positive-hole injecting and transporting layer has liquid-philic properties, while the surface of each region, on which the positive-hole injecting and transporting layer is not formed, has liquid-repellent properties. Therefore, due to the difference in the wettability, the positive-hole injecting and transporting layer can also be formed only on each liquid-phyllic region.

The positive-hole injecting and transporting layer may be a positive-hole injecting layer having a positive-hole injecting function for stably injecting the positive holes, which are injected from the anode, into the luminescent layer, or may be the positive-hole transporting layer having a positive-hole transporting function for transporting the positive holes, which are injected from the anode, into the luminescent layer. In this case, the positive-hole injecting and transporting layer may be formed by laminating the positive-hole injecting layer and positive-hole transporting layer, one on another, or otherwise may be composed of a single layer including both of the positive-hole injecting function and the positive-hole transporting function.

It should be noted that, in this positive-hole-injecting-and-transporting-layer-forming step, it is preferred that the positive-hole injecting layer is formed as the positive-hole injecting and transporting layer, either in the case of forming the single luminescent layer or in the case of collectively forming the positive-hole transporting layer and luminescent layer, by using the luminescent-layer-forming coating liquid containing the quantum dots, around each of which the ligands are attached, and the positive-hole transporting material.

As a positive-hole injecting material used in the positive-hole injecting layer, any suitable material can be used, provided that it can stabilize the injection of the positive holes into the luminescent layer. For example, phenyamines, star-burst-type amines, phthalocyanines, oxides, such as vanadium oxide, molybdenum oxide, ruthenium oxide and aluminum oxide, and electrically conductive polymers, such as amorphous carbon, polyaniline, polythiophene, polyphenylenevinylene and derivatives thereof, can be mentioned. The electrically conductive polymer may be doped with some proper acid. More specifically, as such a material, 4,4′-bis[N-(1-naphthyl)-N-phenyl-amino]-biphenyl (α-NPD), 4,4′,4″-tris(N,N-diphenyl-amino)-triphenylamine (TDATA), 4,4′,4″-tris[N-(3-methylphenyl)-N-phenyl-amino]-triphenylamin e (MTDATA), polyvinylcarbazole, poly(3,4-ethylenedioxythiophene)/polystyrenesulfonic acid (PEDOT/PSS) or the like, can be mentioned. Such materials may be used alone or as a mixture of two or more thereof.

As the film thickness of the positive-hole injecting layer, any suitable thickness can be employed, provided that it can sufficiently exhibit a desired function. Preferably, the thickness is within a range of from 5 nm to 200 nm, and more preferably within a range of from 10 nm to 100 nm.

As the positive-hole transporting material used in the positive-hole transporting layer, any suitable material can be used, provided that it can stably transport the positive holes injected from the anode, into the luminescent layer. For instance, the positive-hole transporting material as described in the above section “3. Luminescent-layer-forming step” can be used.

As the film thickness of the positive-hole transporting layer, any suitable thickness can be employed, provided that it can sufficiently exhibit a desired function. Preferably, this thickness is within a range of from 5 nm to 200 nm, and preferably within a range of from 10 nm to 100 nm.

In this positive-hole-injecting-and-transporting-layer-forming step, the positive-hole transporting layer may be formed, such that this layer can be insoluble to the solvent in the luminescent-layer-forming coating liquid. In this way, upon forming the luminescent layer on the positive-hole injecting and transporting layer, the positive-hole injecting and transporting layer will not be dissolved in the solvent in the luminescent-layer-forming coating liquid, although this solvent contacts with the positive-hole injecting and transporting layer. Therefore, the luminescent layer can be stably laminated on the positive-hole injecting and transporting layer. In addition, deterioration of necessary properties of the positive-hole injecting and transporting layer can be suppressed.

In order to render the positive-hole injecting and transporting layer insoluble to the solvent contained in the luminescent-layer-forming coating liquid, a photo-initiator may be contained in the positive-hole injecting and transporting layer. For instance, the positive-hole injecting and transporting layer may be cured by irradiating it with UV rays, with the photo-initiator, as described in Applied Physics Letter, Vol. 81, (2002), being mixed with the electrically conductive polymer.

Especially, in order to render the positive-hole injecting and transporting layer insoluble to the solvent in the luminescent-layer-forming coating liquid, it is preferred that a curable binder or material, the solubility of which can be changed by an effect of heat energy or radiation, is added to the positive-hole injecting and transporting layer. Namely, it is preferred that a positive-layer-injecting-and-transporting-layer-forming coating liquid contains the positive-hole injecting material and/or positive-hole transporting material together with the curable binder or material, the solubility of which can be changed by an effect of heat energy or radiation.

In particular, it is preferred that the positive-hole injecting and transporting layer is formed, by coating and curing the positive-hole-injecting-and-transporting-layer-forming coating liquid containing the positive-hole injecting material and/or positive-hole transporting material and the curable binder.

Hereinafter, the method for forming the positive-hole injecting and transporting layer will be described, separately, in the case of forming this layer by coating and curing the positive-hole-injecting-and-transporting-layer-forming coating liquid containing the positive-hole injecting material and/or positive-hole transporting material and the curable binder (sixth aspect), and in the case of forming the layer by coating the positive-hole-injecting-and-transporting-layer-forming coating liquid containing the material, the solubility of which can be changed by an effect of heat energy or radiation, and then applying the heat energy or radiation to the coating liquid (seventh aspect).

### (1) Sixth Aspect

In the positive-hole injecting-and-transporting-layer-forming step of this aspect, the positive-hole injecting and transporting layer is formed by coating and curing the positive-hole-injecting-and-transporting-layer-forming coating liquid containing the positive-hole injecting material and/or positive-hole transporting material and the curable binder.

It is noted that the positive-hole injecting material and positive-hole transporting material are the same as those described above.

In this aspect, it is preferred that the positive-hole-injecting-and-transporting-layer-forming step is a positive-hole-injecting-layer-forming step, in which the positive hole injecting layer is formed by coating and curing a positive-hole-injecting-layer-forming coating liquid containing the positive-hole injecting material and the curable binder.

In regard to the curable binder used in this aspect, it is preferable to use a material that can be cured by an effect of heat energy or radiation. For example, a sol-gel reactive liquid, a photo-curing resin and a heat-curing resin can be mentioned. It is noted that the sol-gel reactive liquid means a reactive liquid that can be gelled after cured.

In particular, it is preferred that the curable binder contains the organopolysiloxane. As the oroganopolysloxiane, for example, those described in JP2000-249821A can be used.

The positive-hole-injecting-and-transporting-layer-forming coating liquid is prepared by dispersing and/or dissolving the positive-hole injecting material and/or positive-hole transporting material and the curable binder into the solvent. For instance, in the case in which the curable binder contains the organopolysiloxane, an alcohol-type solvent, such as ethanol, isopropanol or the like, is preferably used as the solvent.

As a method for coating the positive-hole-injecting-and-transporting-layer-forming coating liquid, for example, the spin coating method, spray coating method, dip coating method, roll coating method, bead coating method or the like can be mentioned.

After the positive-hole-injecting-and-transporting-layer-forming coating liquid is coated, it is cured by a proper means. For instance, as a method for curing this liquid, application of some heat energy or suitable radiation can be mentioned.

### (2) Seventh Aspect

In the positive-hole-injecting-and-transporting-layer-forming step of this aspect, the positive-hole injecting and transporting layer is formed by coating the positive-hole-injecting-and-transporting-layer-forming coating liquid containing the material, the solubility of which can be changed by an effect of heat energy or radiation, and then applying the heat energy or radiation to the coating liquid.

As used herein, “the material, the solubility of which can be changed” means that the polarity of this material relative to the solvent, in which a primary component of this material is dissolved and/or dispersed, can be substantially changed. Namely, in the case in which the solubility of such a material, “the solubility of which can be changed,” is changed by application of the heat energy or radiation to the layer containing this material, the polarity (i.e., solubility) of the material relative to the solvent contained in the positive-hole-injecting-and-transporting-layer-forming coating liquid will substantially differ from the polarity (i.e., solubility), relative to the same solvent, of the positive-hole injecting and transporting layer formed with the material after the application of heat energy or radiation.

Preferably, the degree of the change in the solubility of the material is set such that the positive-hole injecting and transporting layer formed after the application of heat energy or radiation will be substantially insoluble or immiscible to the solvent used in the positive-hole-injecting-and-transporting-layer-forming coating liquid. More preferably, the positive-hole injecting and transporting layer after applied with the heat energy or radiation will be completely insoluble to the positive-hole-injecting-and-transporting-layer-forming coating liquid.

In this embodiment, the material, the solubility of which can be changed by the effect of some heat energy or proper radiation, includes a hydrophilic organic material with a part or all of hydrophilic groups thereof converted or changed into lipophilic groups, wherein a part or all of the lipophilic groups can be returned or converted into the hydrophilic groups by the effect of heat energy or radiation.

In such a material, it is not necessary that all of the hydrophilic groups of such a hydrophilic organic material are converted into the lipophilic groups. Any suitable ratio, at which the hydrophilic groups are converted into the lipophilic groups, can be used, provided that the hydrophilic organic material can be dissolved in a typical non-aqueous organic solvent at a desired concentration or higher. Specifically, it is preferred that the hydrophilic groups are converted into the lipophilic groups, such that the hydrophilic organic material dissolved and/or dispersed in water or alcohol-type solvent can be further dissolved in the non-aqueous organic solvent, such as toluene, xylene, ethyl acetate, cyclohexanone or the like, at a concentration of 0.5% by weight or higher.

In the material described above, it is not necessary that all of the lipophilic groups are returned to the hydrophilic groups. Any suitable ratio, at which the lipophilic groups are converted into the hydrophilic groups, can be used, provided that the positive-hole injecting and transporting layer is not dissolved in the solvent of the luminescent-layer-forming coating liquid. Specifically, it is preferred that the lipophilic groups are returned to the hydrophilic groups, such that the material, which can be dissolved in toluene, xylene, ethyl acetate, cyclohexanone or the like, at a concentration of 0.50% by weight or higher, will be insoluble or little soluble to toluene, xylene, ethyl acetate, cyclohexanone or the like. In this case, the material is not necessarily returned to its original hydrophilic organic material.

As the hydrophilic organic material, any suitable material can be used, provided that it has hydrophilic groups for existing proper dispersibility and/or solubility to water, as well as has a desired function required for the positive-hole injecting and transporting layer. In the case in which the positive-hole injecting and transporting layer is the positive-hole injecting layer, for example, those described in JP2006-318876A can be mentioned.

During the conversion for changing the hydrophilic groups in the hydrophilic organic material into the lipophilic groups, a part or all of the resultant hydrophilic groups may be further returned to the hydrophilic groups, due to the effect of heat energy or radiation. Therefore, it is preferable to use a protective reaction for this conversion. As used herein, the “protective reaction” means a reaction in which suitable protective groups are temporarily applied or introduced to the respective hydrophilic groups, so as to change these hydrophilic groups into protected derivatives. As the protective reaction, for example, those described in JP2006-318876A can be mentioned.

The positive-hole-injecting-and-transporting-layer-forming coating liquid can be prepared by dispersing and dissolving the material, which is obtained by converting a part or all of the hydrophilic groups of the hydrophilic organic material into the lipophilic groups, into the solvent. For this preparation, any suitable solvent that can disperse and/or dissolve a hydrophilic material therein can be used. As the solvent, for example, those described in JP2006-318876A can be mentioned.

The concentration of the material, which is obtained by converting a part or all of the hydrophilic groups of the hydrophilic organic material into the lipophilic groups, in the positive-hole-injecting-and-transporting-layer-forming coating liquid, varies with respective components or composition of the material. Usually, the concentration is set at 0.1% by weight or greater, preferably within a range of approximately 1% to 5% by weight.

The positive-hole injecting and transporting layer can be formed by applying heat energy or radiation to the coated film obtained by coating the positive-hole-injecting-and-transporting-layer-forming coating liquid in order to change the solubility of the coated film. In this case, the positive-hole-injecting-and-transporting-layer-forming coating liquid may be dried after it is coated. The application of heat energy and/or radiation may be performed, for example, under conditions described in JP2006-318876A.

An exemplary mechanism, by which the solubility of the material is changed by the effect of heat energy and/or radiation, is detailed in JP2006-318876A.

### 5. Electron-Injecting-and-Transporting-Layer-Forming Step

In this embodiment, an electron-injecting-and-transporting-layer-forming step for forming the electron injecting and transporting layer on the luminescent layer may be provided after the luminescent-layer-forming step. With the provision of such an electron injecting and transporting layer, the injection of the electrons into the luminescent layer can be stabilized, as well as the transportation of the electrons can be performed smoothly. Therefore, the efficiency of emission can be significantly enhanced.

The electron injecting and transporting layer may be an electron injecting layer having an electron injecting function for stably injecting the electrons, which are injected from the cathode, into the luminescent layer, or may be an electron transporting layer having an electron transporting function for transporting the electrons, which are injected from the cathode, into the luminescent layer. In this case, the electron injecting and transporting layer may be formed by laminating the electron injecting layer and electron transporting layer, one on another, or otherwise may be composed of a single layer having both of the electron injecting function and the electron transporting function.

In this electron-injecting-and-transporting-layer-forming step, it is preferred that the electron injecting layer is formed as the electron injecting and transporting layer, in the case in which the single luminescent layer is formed, in the luminescent-layer-forming step, by using the luminescent-layer-forming coating liquid containing the quantum dots, around each of which the ligands are attached, and the electron transporting material.

As the electron injecting material used for the electron injecting layer, any suitable material can be applied, provided that it can stably inject the electrons into the luminescent layer. For example, a single form of alkali metals or alkaline-earth metals, such as Ba, Ca, Li, Cs, Mg, Sr or the like, an alloy of the alkali metals, such as aluminum-lithium alloys or the like, oxides of the alkali metals or alkaline-earth metals, such as magnesium oxide, strontium oxide or the like, fluorides of the alkali metals or alkaline-earth metals, such as magnesium fluoride, calcium fluoride, strontium fluoride, barium fluoride, lithium fluoride, cesium fluoride or the like, and organo-complexes of the alkali metals, such as sodium polymethylmethacrylate-polystyrenesulfonate can be mentioned. Furthermore, such materials may be used in a laminated form, such as Ca/LiF.

Any suitable thickness of the electron injecting layer can be applied, provided that it can sufficiently exhibit a desired function. Preferably, the thickness is within a range of from 0.1 nm to 200 nm, and more preferably within a range of from 0.5 nm to 100 nm.

As the electron transporting material used for the electron transporting layer, any suitable material can be applied, provided that it can stably transport the electrons, which are injected from the cathode, into the luminescent layer. For instance, the electron transporting material as described in the above section “3. Luminescent-layer-forming step” can be used.

As the film thickness of the electron transporting layer, any suitable thickness can be used, provided that it can sufficiently exhibit a desired function. Preferably, the thickness is within a range of from 1 nm to 100 nm, and more preferably within a range of from 1 nm to 50 nm.

As a material for forming the single layer having both of the electron injecting function and the electron transporting function, the electron transporting material doped with the alkali metal or alkaline-earth metal, such as Li, Cs, Ba, Sr or the like, can be mentioned. As the electron transporting material, the phenanthroline derivatives, such as basocuproine (BCP), basophenanthroline (Bpehn) or the like, can be mentioned. The molar ratio between the electron transporting material and the metal doped therein is preferably within a range of from 1:1 to 1:3, and more preferably within a range of from 1:1 to 1:2. Generally, the electron transporting material doped with the alkali metal or alkaline-earth metal has relatively high electron mobility, and also has higher magnetic permeability as compared with the single form of the metal.

As the film thickness of the single layer having both of the electron injecting function and the electron transporting function, any suitable thickness can be employed, provided that it can sufficiently exhibit a desired function. Preferably, the thickness is within a range of from 0.1 nm to 100 nm, and more preferably within a range of from 0.1 nm to 50 nm.

As a method for forming the electron injecting and transporting layer, for example, a dry process, such as the vacuum deposition method, may be used, or otherwise a wet-process, such as the spin coating method may be used. In this embodiment, since the luminescent layer can be cured by using the silane coupling agent as the ligands, the electron injecting and transporting layer can be formed stably on the luminescent layer even in the case of the wet-process.

### 6. Second-Electrode-Layer-Forming Step

In this embodiment, usually, the-second-electrode-layer-forming step for forming the second electrode on the luminescent layer is performed after the luminescent-layer-forming step. In the case in which the electron-injecting-and-transporting-layer-forming step is performed, the second-electrode-layer-forming step for forming the second electrode on the luminescent layer is performed after the electron-injecting-and-transporting-layer-forming step.

The second electrode layer is provided as an opposite electrode to the first electrode layer. Therefore, it may be either of the anode or cathode.

As a material for forming the second electrode layer, any suitable material can be used, provided that it has appropriate electric conductivity. For instance, in the case of outputting light from the second electrode layer, such a second electrode layer preferably has adequate optical transparency. On the other hand, in the case of outputting the light from the first electrode layer, there is no need for the optical transparency of the second electrode layer. It is noted that the material having the electric conductivity is the same as that described in the above section on the first electrode layer. Therefore, the explanation on this material is now omitted.

Furthermore, since the method of forming and patterning the second electrode layer is the same as the method of forming and patterning the first electrode layer described above, the description for this method is also omitted now.

### 7. Insulating-Layer-Forming Step

In this embodiment, prior to the wettability-changing-layer-forming step, an insulating-layer-forming step for forming the insulating layer may be formed at each opening of the pattern of the first electrode layer on the substrate. This insulating layer is provided to shut off the electrical conduction between adjacent pattern segments of the first electrode layer as well as shut off the electrical conduction between the first electrode layer and the second electrode layer. Each portion, on which the insulating layer is formed, corresponds to a non-luminescent region.

The insulating layer is formed at each opening of the pattern of the first electrode layer on the substrate, and is usually provided such that it also covers each edge portion of the pattern of the first electrode layer.

As a material for forming the insulating layer, any suitable material can be used, provided that it has adequate insulating properties. For instance, photosensitive polyimide resins, photo-curing resins such as acryl-type resins, heat-curing resins, inorganic materials or the like can be mentioned.

As a method for forming the insulating layer, a commonly known method, such as the photolithography, printing or the like, can be employed.

### 8. Other Steps

In this embodiment, another step, for forming a barrier layer for protecting the luminescent layer or the like component from influence of oxygen or stream and/or forming a low-refractive-index layer adapted for enhancing efficiency of outputting the light, may be provided.

### II. Second Embodiment

A second embodiment of the manufacturing method for the EL element of this invention includes: the wettability-changing-layer-forming step for forming the wettability changing layer on the substrate having the first electrode layer formed thereon, wherein the wettability of the wettability changing layer is changed by an effect of the photocatalyst associated with irradiation with energy; the wettability-changing-pattern-formign step for forming the wettability changing pattern composed of the lyophilic regions and liquid-repellent regions, on a surface of the wettability changing layer, by irradiating the wettability changing layer with energy in a patterning manner, after a photocatalyst-processing-layer base, on which a photocatalyst-processing layer containing at least the photocatalyst is formed, is located over the surface of the wettability changing layer, with a gap that allow the effect of the photocatalyst associated with the irradiation with energy to be exerted on the wettability changing layer; and the luminescent-layer-forming step for forming the luminescent layer by coating the luminescent-layer-forming coating liquid containing the quantum dots, around each of which the ligands are attached, onto each lyophilic regions.

Hereinafter, the manufacturing method for the EL element of this embodiment will be described with reference to the drawings.

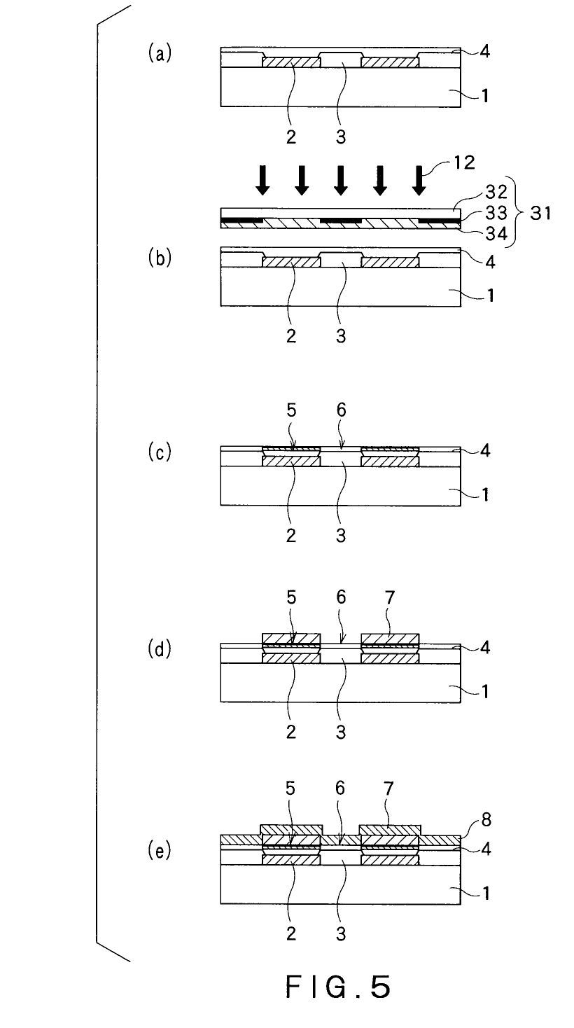

FIG. 5 is a flow chart illustrating several steps of one example of the manufacturing method for the EL element related to this embodiment. First, the first electrode layer 2 is formed into a pattern-like shape on the substrate 1. Then, the insulating layer 3 is formed at each opening of the pattern. Thereafter, the wettability changing layer 4 is formed on the first electrode layer 2 and each insulating layer 3 (FIG. 5(a): the wettability-changing-layer-forming step).

Subsequently, as shown in FIG. 5(b), a photocatalyst-processing-layer substrate (or photocatalyst-processing-layer base) 31, including a base 32, a light shielding part 33 formed on the base 32 into a pattern-like shape, and a photocatalyst processing layer 34 formed on the base 32 such that it covers the light shielding part 33, is prepared. Thereafter, the photocatalyst processing layer 34 of the photocatalyst-processing-layer base 31 is arranged to be opposed to the wettability changing layer 4, and ultraviolet rays 12 are then radiated onto the wettability changing layer 4 via the photocatalyst-processing-layer base 35. With such irradiation with the ultraviolet rays 12, as shown in FIG. 5(c), the wettability is changed such that the contact angle relative to the liquid will be lowered, in each irradiated portion of the wettability changing layer 4, due to the effect of the photocatalyst contained in the photocatalyst processing layer 34. The portions or regions in which the wettability is changed such that the contact angle relative to the liquid is lowered will be referred to as “Iyophilic regions 5.” It is noted that the wettability is not changed in each non-irradiated portion. Such portions or regions, in which the wettability is not changed, will be referred to as “liquid-repellent regions 6.” Thereafter, the photocatalyst-processing-layer substrate 31 is removed from the wettability changing layer 4. In this way, the wettability changing pattern composed of the lyophilic regions 5 and liquid-repellent regions 6 is formed on the surface of the wettability changing layer 4. Namely, FIGS. 5(b) and 5(c) show the wettability-changing-pattern-forming step, respectively.

In the wettability changing layer 4 is configured such that the wettability thereof can be changed by the effect of the photocatalyst associated with the irradiation with energy. Therefore, there is a substantial difference in the wettability between the lyophilic regions 5 respectively corresponding to the irradiated portions and the liquid-repellent regions 6 respectively corresponding to the non-irradiated portions.

Thereafter, the luminescent-layer-forming coating liquid is coated on the wettability changing layer pattern composed of the lyophilic regions 5 and liquid-repellent regions 6, so as to form a patterned luminescent layer 7 formed only on each lyophilic regions 5, by utilizing the difference in the wettability (FIG. 5(d): the luminescent-layer-forming step).

The luminescent-layer-forming coating liquid contains the quantum dots 22, around each of which the ligands 21 are attached, as shown in FIG. 2. Namely, the ligands 21 are attached to a surface of each quantum dot 22, and such quantum dots 22, around each of which the ligands 21 are attached, are contained in the luminescent-layer-forming coating liquid.

Next, the second electrode 8 is formed on the luminescent layer 7 (FIG. 5(e)). Upon this step, for example, in the case in which an optically transparent electrode is used as the second electrode 8, the top-emission-type EL element can be obtained. However, in the case in which such an optically transparent electrode is used as the first electrode 2, the bottom-emission-type EL element can be obtained.

In this embodiment, the wettability changing pattern composed of the lyophilic regions and liquid-repellent regions is formed on the surface of the wettability changing layer, by irradiating the wettability changing layer with energy, via the photocatalyst processing layer containing the photocatalyst. In this way, the patterning of the luminescent layer can be achieved by utilizing the wettability changing pattern formed on the surface of the wettability changing layer. Accordingly, the patterning of the luminescent layer can be carried out with ease, without a need for performing complicated patterning steps and/or preparing expensive vacuum equipment.

In this embodiment, the wettability of the wettability changing layer not containing the photocatalyst can be changed by the effect of the photocatalyst, by irradiating such a wettability changing layer with energy, in a patterning manner, via the photocatalyst processing layer containing the photocatalyst. Additionally, after the wettability changing pattern is formed on the surface of the wettability changing layer, the photocatalyst-processing-layer substrate having the photocatalyst processing layer formed thereon is removed from the wettability changing layer. Therefore, the photocatalyst is not contained in the EL element itself. Namely, the photcatalyst is contained in the photocatalyst processing layer, but is not contained in the wettability changing layer. Accordingly, smoothness of the wettability changing layer can be enhanced, thus reducing negative influence due to the interface that would be otherwise created between the wettability changing layer and the luminescent layer. Thus, the driving voltage can be reduced, as well as the luminance and efficiency of emission can be enhanced, as such significantly improving the emission properties. Furthermore, this construction can avoid or prevent a short between the electrodes.

In this embodiment, it is preferred that the ligands attached to the surface of each quantum dot are formed from a silane coupling agent. Consequently, the luminescent layer can be provided as a cured form, thus enhancing the stability of each quantum dot in the luminescent layer, thereby improving the life properties. Generally, a molecular design for such a silane coupling agent can be carried out with ease. Therefore, by using the silane coupling agent having functional groups for exhibiting a variety of functionality, the life properties can be securely improved.

Furthermore, it is preferred that the wettability changing layer contains the organopolysiloxane. In this case, the organopolysiloxane contained in the wettability changing layer will be coupled with the first electrode layer, while the silane coupling agent contained in the luminescent layer will be coupled with the wettability changing layer. Consequently, the adhesion ability between the first electrode layer and the wettability changing layer can be positively enhanced. Accordingly, degradation of the life properties caused by interlayer peeling or detachment during operation of the EL element and the like can be prevented.

It is noted that the luminescent-layer-forming step of this embodiment is the same as that discussed in the first embodiment. Therefore, the description on this step is now omitted. Hereinafter, the other steps of the manufacturing method for the EL element will be described.

### 1. Wettability-Changing-Layer-Forming Step

In the wettability-changing-layer-forming step of this embodiment, the wettability changing layer, in which the wettability is changed by the effect of the photocatalyst associated with the irradiation with energy, is formed on the substrate having the first electrode layer formed thereon.

The wettability changing layer used in this embodiment is inert to the energy. As used herein, the “energy” means the energy radiated or applied for rendering the photcatalyst active. Specifically, the ultraviolet rays can be mentioned as the energy. Moreover, “the wettability changing layer is inert to the energy” means that each component of the wettability changing layer shows or causes no reaction after the wettability changing layer is irradiated with such ultraviolet rays or the like.

More specifically, while the wettability changing layer in this embodiment can be reactive due to the effect of the photocatalyst, it will not cause any reaction, in the absence of the photocatalyst, even though irradiated with energy. Namely, the expression “the wettability changing layer is inert to the energy” means that the wettability changing layer contains substantially no photocatalyst.

For example, “the wettability contains substantially no photocatalyst” means that the content of the photocatalyst in the wettability changing layer is 1% by weight or less.

In this manner, since the wettability changing layer in this embodiment contains substantially no photocatalyst, the smoothness of this layer can be enhanced, thereby to reduce the negative influence due to the interface that would be otherwise created between the wettability changing layer and the luminescent layer. Thus, the driving voltage can be reduced, as well as the luminance and efficiency of emission can be enhanced, thereby significantly improving the emission properties. In addition, such construction can avoid or prevent a short between the electrodes.

As the wettability changing layer, any suitable layer can be employed, provided that the wettability of the layer can be appropriately changed by the effect of the photcatalyst associated with the irradiation with energy. Further, as a material for forming the wettability changing layer, any suitable material can be used, provided that the wettabiltiy of this material can be appropriately changed due to the effect of the photocatalyst associated with the irradiation with energy, and that this material has a main chain, which is unlikely to be degraded or decomposed by the effect of the photocatalyst. As such a material used for the wettability changing layer, for example, (1) organopolysiloxane, which can be obtained through hydrolysis and polycondensation of chloro- or alkoxy-silanes and the like monomers in a sol-gel reaction or the like, thus exhibiting considerably high strength, (2) organopolysiloxane, in which reactive silicones, each having excellent water-repellent properties and/or oil-repellent properties, are cross-linked together, and the like organopolysiloxane, can be mentioned.

Since the organopolysiloxane used in this embodiment is the same as that discussed in the first embodiment, the explanation on this material is now omitted.

Alternatively or additionally, a relatively stable organosilicone compound (e.g., dimethylpolysiloxane) that causes no cross-linking reaction, may be mixed with the aforementioned organopolysiloxane.

In this way, various materials, such as organopolysiloxane and the like, can be used for the wettability changing layer. Especially, it is preferred that the wettability changing layer contains fluorine.

It is noted that the case, in which the wettability changing layer contains fluorine, has been discussed in the first embodiment. The description on such a case is now omitted.

Other than those described above, suitable surfactants and/or other additives, as disclosed in JP2000-249821A, may be added to the wettability changing layer.

It is noted that the method for forming the wettaibltiy changing layer and the film thickness thereof are the same as those described in the first embodiment. Therefore, the explanation on these matters is now omitted.

### 2. Wettability-Changing-Pattern-Forming Step

In the wettability-changing-pattern-forming step of this embodiment, the wettability changing pattern composed of the lyophilic regions and liquid-repellent regions is formed on the surface of the wettability changing layer, by irradiating the wettability changing layer with energy in a patterning manner, after the photocatalyst-processing-layer substrate or base, on which the photocatalyst-processing layer containing at least the photocatalyst is formed, is located over the surface of the wettability changing layer, with the gap that allow the effect of the photocatalyst associated with the irradiation with energy to be exerted on the wettability changing layer.

Hereinafter, the photocatalyst-processing-layer substrate, arrangement of the photocatalyst-processing-layer substrate and wettability changing layer, irradiation with energy and wettability changing pattern will be described, respectively.

### (1) Photocatalyst-Processing-Layer Substrate (Photocatalyst-Processing-Layer Base)

In this embodiment, upon forming the wettabiltiy changing pattern on the surface of the wettability changing layer, in which the wettability is changed by the effect of the photocatalyst associated with the irradiation with energy, the photcatalyst-processing-layer substrate having the photocatalyst processing layer containing the photocatalyst is used for exerting the effect of the photocatalyst on the wettability changing layer. Due to such irradiation with energy applied or radiated in a patterning manner, while the photocatalyst-processing-layer substrate is located over the wettability changing layer with a predetermined gap, the wettability changing pattern can be formed on the surface of the wettability changing layer.

The photcatalyst-processing-layer substrate used in this embodiment includes the base and the photocatalyst processing layer formed on the base. Additionally, the light shielding part may be formed, into a pattern-like shape, on the photocatalyst-processing-layer substrate. Hereinafter, the photocatalyst processing layer, base and light shielding part will be described.

### (i) Photocatalyst Processing Layer

The photocatalyst processing layer used in this embodiment contains the photocatalyst. As the photocatalyst processing layer, any suitable layer can be used, provided that the photocatalyst contained in this layer can appropriately change the wettability of the surface of the wettability changing layer. This photocatalyst processing layer may be composed of, for example, the photcatalyst and a suitable binder, or may be composed of only the photocatalyst. In the case of the photocatalyst processing layer composed of only the photocatalyst, the efficiency of changing the wettability of the surface of the wettability changing layer can be significantly enhanced, as such substantially reducing the time required for the process. This is advantageous to the cost. Otherwise, in the case of the photocatalyst processing layer composed of the photocatalyst and binder, such a photocatalyst processing layer can be securely formed with ease.

It is noted that the photcatalyst used in this embodiment is the same as that described in the first embodiment. Therefore, the explanation of this material will be omitted hereinafter.

In the case in which the photocatalyst processing layer is composed of the photocatalyst and binder, the binder is preferably has high bond energy such that a main chain thereof will not be decomposed by photo-excitation due to the photocatalyst. As such a binder, for example, the organopolysiloxane as described above or the like can be mentioned.

Furthermore, an amorphous silica precursor may be used as the binder. As the amorphous silica precursor, silicon compounds that can be expressed by the general formula: SiX4, in which X is halogen, methoxy group, ethoxy group, acetyl group or the like, can be mentioned. Preferably, silanols, i.e., hydrolyzates, of such silicon compounds, or polysiloxanes having an average molecular weight of 3000 or less are used as the amorphous silica precursor. More specifically, tetraethoxysilane, tetraisopropoxysilane, tetra-n-propoxysilane, tetrabutoxysilane, tetramethoxysilane and the like can be mentioned. Such materials may be used alone or as a mixture of two or more thereof.

In the case in which the photocatalyst processing layer is composed of the photocatalyst and binder, the content of the photocatalyst in such a photocatalyst processing layer is usually set within a range of from 5% to 60% by weight, preferably within a range of from 20% to 50% by weight.

Other than the photocatalyst and binder described above, suitable surfactants and/or other additives, as those described in JP2000-249821A, may be added to the photocatalyst processing layer.

The thickness of the photocatalyst processing layer is preferably within a range of from 0.01 μm to 10 μm.

The wettability of the surface of the photocatalyst processing layer may exhibit liquid-philic properties or liquid-repellent properties.

As a method for forming the photocatalyst processing layer composed of only the photocatalyst, for example, a vacuum film-forming method, such as the CVD method, spattering method, vacuum deposition method or the like, can be mentioned. With such a vacuum film-forming method, the photocatalyst processing layer constituting a uniform film and containing only the photocatalyst can be formed. In this way, the wettability of the surface of the wettability changing layer can be uniformly changed. In addition, since the photcatalyst processing layer is composed of only the photocatalyst, the wettabiltiy of the surface of the wettability changing layer can be changed more efficiently, as compared with the case of additionally using the binder.

For example, in the case in which titanium dioxide is used, as the photocatalyst, in the method for forming the photocatalyst processing layer composed of only the photocatalyst, a film of amorphous titania is first formed on the base, and the so-formed amorphous titania film is then subjected to calcination and thus changed into a crystalline titania phase.

The amorphous titania can be obtained by subjecting an inorganic salt, such as titanium tetrachloride, titanium sulfate or the like, to hydrolysis and then dehydration condensation, or otherwise it can be obtained by subjecting an organo-titanium compound, such as tetraethoxy titanium, tetraisopropoxy titanium, tetra-n-propoxy titanium, tetrabutoxy titanium, tetramethoxy titanium or the like, to hydrolysis and then dehydration condensation, in the presence of a proper acid. Thereafter, when the so-obtained amorphous titania is calcinated at 400° C. to 500° C., it can be changed into the anatase-type titania. Otherwise, when such amourphous titania is calcinated at 600° C. to 700° C., it can be modified into the rutile-type titania.

In the case in which the organopolysiloxane is used, as the binder, in a method for forming the photocatalyst processing layer composed of the photocatalyst and binder, for example, a photocatalyst-processing-layer-forming coating liquid may be first prepared by dispersing the photocatalyst and organopolysiloxane as the binder into a solvent together with other additive as required, and then coated on the base. Alternatively or additionally, in the case in which the binder contains a UV-curing component, the ultraviolet rays may be used for curing the coating liquid after it is coated.

As the solvent used for this process, a proper alcohol solvent, such as ethanol, isopropanol or the like, is preferably used. In addition, as the coating method, a commonly known method, such as the spin coating, spray coating, dip coating, roll coating, bead coating or the like, can be used.

In the case of using the amorphous silica precursor, as the binder, in the method for forming the photocatalyst processing layer composed of the photcatalyst and binder, the photocatalyst-processing-layer-forming coating liquid may be first prepared by uniformly dispersing particles of the photocatalyst and amorphous silica precursor into a proper non-aqueous solvent, and then coated on the base. Thereafter, the amorphous silica precursor is subjected to the hydrolysis with moisture in the air, and thus changed into the silanol. Further, the so-obtained silanol is subjected to the dehydration polycondensation at a normal temperature. In this case, if the dehydration polycondensation for the silanol is conducted at 100° C. or higher temperature, the degree of polymerization of the silanol can be increased, as such enhancing the strength of the film surface.

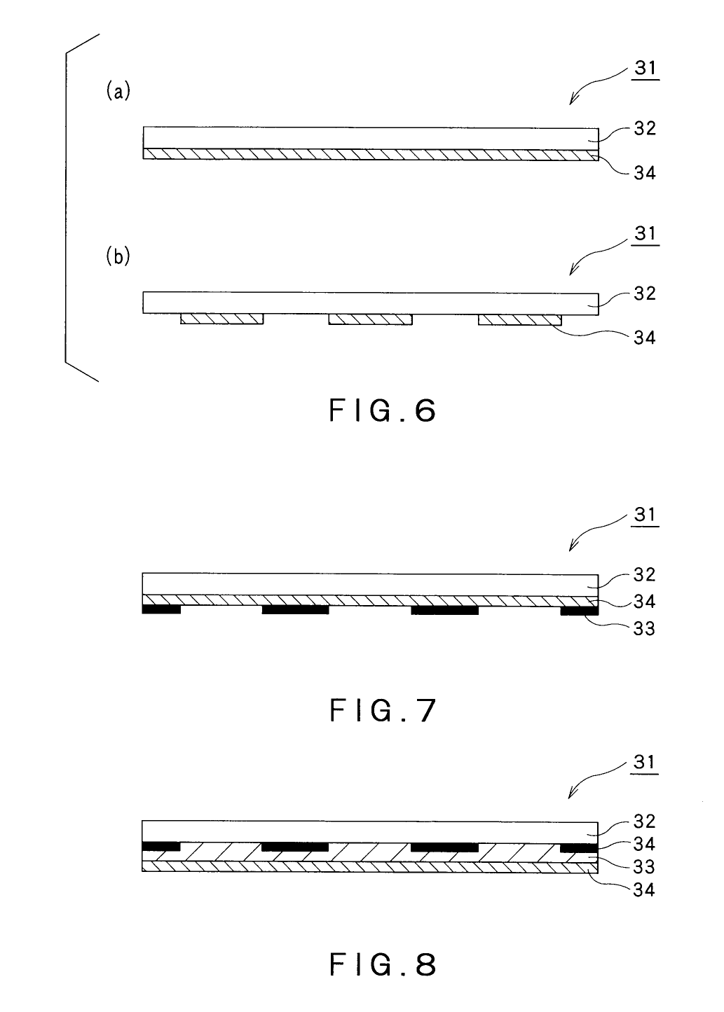

The photocatalyst processing layer 34 may be formed over the whole surface of the base 32, for example, as shown in FIG. 6(a), or otherwise may be formed on the base 32, into a pattern-like shape, for example, as shown in FIG. 6(b).

In the case in which the photocatalyst processing layer is formed in the pattern-like shape, there is no need for using the photomask or the like, upon performing the irradiation with energy onto the surface of the wettability changing layer. Namely, the wettability of the surface of the wettbility changing layer can be changed, in a patterning manner, due to the irradiation of energy over the whole surface of the wettability changing layer, by only arranging such a photocatalyst processing layer over the wettability changing layer with a predetermined gap. In this case, since the wettability can be changed only in the surface of the wettability changing layer actually facing the photocatalyst processing layer, any given irradiation direction of the energy can be employed, provided that the energy can be adequately applied to the surface of the wettability changing layer. Additionally, the energy applied to the surface of the wettability changing layer is not necessarily limited to parallel beams.

Any suitable method for patterning the photocatalyst processing layer can be used. For example, the photolithography or the like can be mentioned.

### (ii) Base

In regard to the base used for the photocatalyst-processing-layer substrate, the optical transparency is suitably selected, based on the irradiation direction of energy that will be described later and/or based on an output direction of light emitted from the EL element that will be obtained by using this substrate.

For instance, in the case in which the EL element, as shown in FIG. 5(e), is the top-emission type element and the substrate or first electrode layer of this EL element is not optically transparent, the irradiation with energy should be performed on the side of the photocatalyst-processing-layer substrate. In addition, for example, in the case in which the shielding part 33 is formed in the photocatalyst processing layer substrate 31, as shown in FIG. 5(b), and in which the energy is radiated, in a patterning manner, via the light shielding part 33, the irradiation with energy should be performed on the side of the photocatalyst-processing-layer substrate. Therefore, in such cases, the base should have the optical transparency.

On the other hand, in the case in which the EL element, as shown in FIG. 5(e), is the bottom-emission type element, the irradiation with energy should be performed on the side of the substrate of this EL element. Therefore, in this case, the base is not required to have the optical transparency.

The base may be a flexible material, such as a resin-based film or the like, or otherwise may be a non-flexible material, such as a grass substrate or the like.

Any suitable material can be used as the photocatalyst-processing-layer base. However, because this base is used repeatedly, it is necessary that this material has desired strength. More preferably, this base has a surface having excellent adhesion properties to the photocatalyst processing layer. More specifically, as the material for constituting the base, glass, ceramic, metal, plastic or the like can be mentioned.

In order to enhance the adhesion properties between the surface of the base and the surface of the photocatalyst processing layer, an anchor layer may be provided on the base. As a material for forming the anchor layer, for example, a silane-based or titanium-based coupling agent can be mentioned.

(iii) Light Shielding Part

In the photocatalyst-processing-layer substrate used in this embodiment, the light shielding part may be formed into a pattern-like shape. In the case of using the photocatalyst-processing-layer substrate having such a pattern-like light shielding part, there is no need for using the photomask or radiating energy to depict a desired pattern. Accordingly, in this case, since there is no need for alignment between the photocatalyst-processing-layer substrate and the photomask, the irradiation process can be facilitated. Besides, a need for an expensive apparatus that might be otherwise required for depicting a desired pattern can be eliminated. This is significantly advantageous to the cost.

In the method of forming the light shielding part 33, for example, as shown in FIG. 5(b), the light shielding part 33 may be first formed, into a pattern-like shape, on the base 32, and then the photocatalyst processing layer 34 may be formed on the light shielding layer 33. Otherwise, as shown in FIG. 7, the photocatalyst processing layer 34 may be first formed on the base 32, and then the light shielding part 33 may be formed, into the pattern-like shape, on the base 32. Although not shown, the light shielding part 33 may also be formed, into such a pattern-like shape, on the surface of the base, on which the photocatalyst processing layer is not formed.

In the case in which the light shielding layer is formed on the base or in the case in which the light shielding layer is formed on the photocatalyst processing layer, the light shielding part can be positioned nearer to a portion in which the photocatalyst processing layer and wettability changing layer are arranged with the predetermined gap therebetween, as compared with the case of using the photomask. Thus, scattering of energy or the like negative influence in the base can be reduced. Therefore, the irradiation with energy in a patterning manner can be performed with significant accuracy.

Moreover, in the case in which the light shielding part is formed on the photocatalyst processing layer, this light shielding part can be used as a spacer that can serve to keep the predetermined gap constant, between the photocatalyst processing layer and the wettability changing layer, by matching the film thickness of the light shielding part with the size of the gap. Namely, upon arranging the photocatalyst processing layer and wettability changing layer with the predetermined gap provided therebetween, such a predetermined gap can be kept constant, by positioning the light shielding part while allowing it to be contacted with the wettability changing layer. In this manner, when the energy is radiated or applied onto the wettabiltiy changing layer through the photocatalyst-processing-layer substrate, the wettability changing pattern can be formed on the surface of the wettability changing layer with high precision.

In the case in which the light shielding part is formed on the surface of the base, on which the photocatalyst processing layer is not formed, for example, a suitable photomask can be adhered closely to the surface of the light shielding part such that the photomask can be detached from the surface. Such arrangement can be applied to the case in which the production of the EL elements is altered for each small lot.

Any suitable method for forming the light shielding part can be employed, provided that necessary features on a face constituting the light shielding part and required light shielding properties against the energy can be adequately provided.

For instance, the light shielding part can be formed by preparing a metal thin film of chromium or the like, having a thickness of approximately 1000 Å to 2000 Å, by using the spattering method, vacuum deposition method or the like, and then patterning the so-prepared thin film. As a method for this patterning, a commonly known method can be employed.

Alternatively or additionally, the light shielding part can be formed by patterning a layer composed of a resin binder containing light shielding particles, such as carbon fine particles, metal oxide, inorganic pigment, organic pigment or the like. As the resin binder, a polyimide resin, an acryl resin, an epoxy resin, polyacrylamide, polyvinyl alcohol, gelatin, casein, cellulose and the like can be mentioned. Such resins can be used alone or as a mixture of two or more thereof. Alternatively or additionally, as the resin binder, a photosensitive resin or O/W-emulsion-type resin composition, e.g., a composition obtained by emulsifying a reactive silicone or the like, can be used. As the method for the patterning, the photolithography, printing, and other commonly known patterning methods can be employed.

The thickness of the light shielding part using such a resin binder can be set within a range of from 0.5 μm to 10 μm.

### (iv) Primer Layer

In this embodiment, in the case in which the light shielding part is formed into the pattern-like shape on the base, as described above, and in which the photocatalyst processing layer is formed on the light shielding layer, for example, as shown in FIG. 8, it is preferred that a primer layer 35 is provided between the light shielding layer 33 and the photocatalyst processing layer 34.

While an effect and/or function of this primer layer is now still being elucidated, such a layer is considered to have a function for preventing impurities, present in the light shielding part and each opening between respective pattern segments of the light shielding part, from being diffused from. Namely, such impurities, especially residues produced upon pattering the light shielding part, and metals or metal ions, will substantially interfere with the change of wettability in the wettability changing layer due to the effect of the photocatalyst. Accordingly, with the provision of such a primer layer between the light shielding layer and the photocatalyst processing layer, the process for changing the wettability can be promoted with high sensitivity, thereby to obtain the wettability changing pattern with a higher resolution.

Since the primer layer is considered to prevent the impurities, present in the blocking part as well as in each opening between the light shielding pattern segments, from exerting negative influence on the effect of the photocatalyst, it is preferred that this primer layer is formed to cover the whole surface including the pattern-like light shielding layer and each opening between the light shielding pattern segments. In this case, the primer layer is preferably formed to prevent physical contact between the photocatalyst processing layer and the light shielding layer.

As a material for constituting this primer layer, any suitable material can be used. Preferably, an inorganic material, which is unlikely to be decomposed by the effect of the photocatalyst, is used as the material. As such an inorganic material, for example, an amorphous silica can be mentioned. As the precursor of such an amorphous silica, the silicon compounds that can be expressed by the general formula: SiX4, in which X is halogen, methoxy group, ethoxy group, acetyl group or the like, can be mentioned. Preferably, silanols, i.e., hydrolyzates of such silicon compounds, or polysiloxanes having an average molecular weight of 3000 or less are used as such an amorphous silica precursor.

The film thickness of the primer layer is preferably within a range of from 0.001 μm to 1 μm, and more preferably within a range of from 0.001 μm to 0.5 μm.

### (2) Arrangement of the Photocatalyst-Processing-Layer Substrate and Wettability Changing Layer

In this embodiment, the photocatalyst-processing-layer substrate is arranged, relative to the wettability changing layer, with the gap that allow the effect of the photocatalyst associated with the irradiation with energy to be exerted on the wettability changing layer. Usually, the photocatalyst processing layer of the photocatalyst-processing-layer substrate and the wettability changing layer are arranged, with the gap provided therebetween such that it allows the effect of the photocatalyst associated with the irradiation with energy to be exerted on the wettability changing layer.

It is noted that this “gap” also includes such a state that the photocatalyst processing layer is in contact with the wettability changing layer.

Preferably, the gap between the photocatalyst processing layer and the wettability changing layer is 200 μm or less. Due to the arrangement of the photocatalyst processing layer and wettability changing layer with such a predetermined gap, active oxygen species, generated from oxygen, hydrogen and/or effect of the photocatalyst, can be readily attached or detached relative to the wettability changing layer. If the gap between the photocatalyst processing layer and the wettability changing layer is wider than the aforementioned range (i.e., 200 μm or less), the active oxygen species generated by the effect of the photocatalyst will be difficult to reach the wettability changing layer, thus delaying the change of wettability. Contrary, if the gap between the photocatalyst processing layer and the wettability changing layer is unduly small, the active oxygen species generated by the effect of the photocatalyst will be unlikely to be attached or detached relative to the wettability changing layer, thus also delaying the change of wettability.

In view of enhancement and/or improvement of accuracy of the pattern, sensitivity of the photocatalyst and efficiency of the change of wettabiltiy, the aforementioned gap is preferably within a range of from 0.2 μm to 20 μm, and more preferably within a range of from 1 μm to 10 μm.

In the case of manufacturing a large-sized EL element of, for example, a 300 mm×300 mm size, it is quite difficult to provide such a small gap as described above between the photocatalyst-processing-layer substrate and the wettability changing layer. Accordingly, in the case of manufacturing such a large-sized EL element, the gap is preferably within a range of from 5 μm to 100 μm, and more preferably within a range of from 10 μm to 75 μm. With the gap set within such a range, degradation of the pattern accuracy, such as blurring, can be adequately controlled, as well as deterioration of the efficiency of the change of wettability due to degradation of the sensitivity of the photocatalyst can be avoided.

Upon radiating the energy onto such a large-sized component as described above, the gap between the photocatalyst-processing-layer substrate and the wettability changing layer, provided in the apparatus irradiated with the energy and set by a proper positioning mechanism, is preferably within a range of from 10 μm to 200 μm, and more preferably within a range of from 25 μm to 75 μm. With the gap set within this range, adequate arrangement of the photocatalyst-processing-layer substrate and wettability changing layer can be achieved, without leading to drastic degradation of the pattern accuracy as well as serious deterioration of the sensitivity of the photocatalyst, while of course avoiding direct contact between the photocatalyst-processing-layer substrate and the wettability changing layer.

In this embodiment, the arrangement with the gap as described above should be maintained at least only in a period of time required for the irradiation with energy.

As a method for arranging the photocatalyst processing layer and wettability changing layer with such a quite small gap uniformly provided therebetween, for example, a method employing a proper spacer or spacers can be mentioned. With such a method employing the spacer o spacers, a substantially uniform gap can be provided, as well as the effect of the photocatalyst will not be exerted on the surface of the wettability changing layer in a portion contacting with or shielded by such a spacer. Therefore, by providing such a spacer to have the same pattern as the aforementioned wettability changing pattern, an alternate desired wettability changing pattern can be formed on the surface of the wettability changing layer.

In this embodiment, the spacer may be formed separately as a single member. Preferably, for simplification of the process or the like, such a spacer is formed, in advance, on the photocatalyst processing layer of the photocatalyst-processing-layer substrate. This can also provide the advantages as described in the above section “(iii) Light shielding part.”

The spacer should have at least a function for protecting the surface of the wettability changing layer in order to prevent the effect of the photocatalyst from being exerted on the surface of the wettability changing layer. Therefore, the spacer may not have complete shielding properties against the energy applied.

(3) Irradiation with Energy

In this embodiment, the wettability changing pattern is formed on the surface of the wettabiltiy changing layer, by irradiating the wettability changing layer with energy, in a desired patterning manner and in a predetermined direction, after the photocatalyst processing layer and wettability changing layer are suitably arranged with the predetermined gap therebetween.

Since the wavelength of light and light source used for this irradiation with energy are the same as those discussed in the first embodiment, the description on these matters is now omitted.

The amount of energy applied upon the irradiation is selected, as required, for adequately changing the wettability of the surface of the wettability changing layer, by utilizing the effect of the photocatalyst contained in the photocatalyst processing layer.

In this case, it is preferred that the irradiation with energy is performed while heating the photocatalyst processing layer. This is because the sensitivity can be increased, thus enhancing the efficiency of changing the wettability. Preferably, the heating is performed at a temperature within a range of from 30° C. to 80° C.

The irradiation direction of energy depends on whether or not the light shielding part is formed on the photocatalyst-processing-layer substrate, or depends on the output direction of the EL element.

For instance, in the case in which the light shielding part is formed on the photocatalyst-processing-layer substrate and the base of this photocatalyst-processing-layer substrate is optically transparent, the irradiation with energy is performed on the side of the photocatalyst-processing-layer substrate. In addition, in the case in which the light shielding part is formed on the photocatalyst processing layer and this light shielding part can serve as the spacer, the irradiation direction of energy may be performed on the side of the photocatalyst-processing-layer substrate or on the side of the base.

Alternatively, in the case in which the photocatalyst processing layer is formed into a pattern-like shape, the irradiation direction of energy, as described above, may be any suitable direction, provided that the energy can be adequately radiated onto a portion in which the photocatalyst processing layer and wettability changing layer face each other.

Similarly, also in the case of using the spacer, the irradiation direction of energy may be any desired direction, provided that the energy can be properly radiated onto the portion in which the photocatalyst processing layer and wettability changing layer face each other.

Furthermore, in the case of using the photomask, the energy should be radiated on the side where the photomask is located. In this case, the side on which the photomask is located should be optically transparent.

After the irradiation with energy, the photocatalyst-processing-layer substrate will be removed from the wettabiltiy changing layer.

### (4) Wettability Changing Pattern

The wettability changing pattern of this embodiment is formed on the surface of the wettability changing layer, and is composed of the lyophilic regions and liquid-repellent regions.

It is noted that the contact angle relative to the liquid of each of the lyophilic regions and liquid-repellent regions is similar to that described in the first embodiment. The explanation on this feature is now omitted.

### 3. Other Steps

Also in this embodiment, the positive-hole-injecting-and-transporting-layer-forming step, electron-injecting-and-transporting-layer-forming step, insulating-layer-forming step and the like can be performed in the same manner as discussed in the first embodiment.

Usually, the second-electrode-layer-forming step is also conducted in the same manner as in the first embodiment.

### B. EL Element

The EL element according to this invention includes: the first electrode layer formed into a pattern-like shape on the substrate; the wettability changing layer which is formed on the first electrode layer and configured such that the wettability thereof is changed by the effect of the photocatalyst associated with the irradiation with energy, and which has the wettability changing pattern composed of the lyophilic regions located on the pattern of the first electrode layer and containing polysiloxane and the liquid-repellent regions located on each opening of the pattern of the first electrode layer and containing organopolysiloxane containing fluorine; the luminescent layer formed on each lyophilic regions of the wettability changing layer; and the second electrode layer formed on the luminescent layer, wherein the quantum dots, around each of which the silane coupling agent is attached, is used in the luminescent layer.

In the EL element exemplarily shown in FIG. 1(e), the first electrode 2 is formed in a pattern-like shape on the substrate 1, and the insulating layer 3 is then formed on each opening of the pattern of the first electrode layer 2. Thereafter, the wettability changing layer 4 is formed on both of the first electrode 2 and insulating layer 3, and the wettability changing pattern composed of the lyophilic regions 5 and liquid-repellent regions 6 is formed on the surface of the wettability changing layer 4. Subsequently, the luminescent layer 7 is formed on each liquid-philic layer 5, and the second electrode layer 8 is then formed on the luminescent layer 7. Each liquid-philic layer 5 on the surface of the wettability changing layer 4 contains polysiloxane, and is formed on the pattern of the first electrode layer 2. On the other hand, each liquid-repellent region 6 on the surface of the wettability changing layer 4 contains organopolysiloxane containing fluorine and is formed on each opening of the pattern of the first electrode 2, i.e., on each insulating layer 3.

Generally, fluorine renders the surface energy substantially lowered. Therefore, a surface of a material containing a lot of fluorine tends to exhibit considerably reduced critical surface tension. Therefore, the critical surface tension in a portion of the surface containing less fluorine should be greater than that in another portion of the surface containing more fluorine.

In this invention, each lyophilic regions on the surface of the wettability changing layer contains polysiloxane, while each liquid-repellent region on the surface of the wettability changing layer contains organopolysiloxane containing fluorine. Thus, the content of fluorine in each liquid-repellent region can be considered to be greater than the content of fluorine in each lyophilic regions. Accordingly, the critical surface tension of each lyophilic regions can be considered to be greater than the critical surface tension of each liquid-repellent region.

In this manner, the critical surface tension or wettability differs between each liquid-repellent region and each lyophilic regions. Thus, by utilizing such a difference of the wettability between each liquid-repellent region and each lyophilic regions, the luminescent layer can be formed only on each lyophilic regions. Accordingly, the EL element can be provided, in which the luminescent layer can be patterned with ease, without a need for performing complicated patterning steps and/or preparing expensive vacuum equipment.

Additionally, in this invention, since the quantum dots, around each of which the silane coupling agent is attached, are used in the luminescent layer, the stability of such quantum dots in the luminescent layer can be improved, thus leading to substantial enhancement of the life properties. Besides, the thermo-stability of the luminescent layer (i.e., Tg: glass-transition temperature) can be improved. In addition, the molecular design for such a silane coupling agent can be carried out with ease. Therefore, by using such a silane coupling agent having functional groups for exhibiting a variety of functionality, the life properties can be further improved.

Moreover, since each lyophilic regions on the surface of the wettability changing layer contains polysiloxane while each liquid-repellent region on the surface of the wettbility changing layer contains organopolysiloxane containing fluorine, as well as because the luminescent layer contains the quantum dots, around each of which the silane coupling agent is attached, the organopolysiloxane contained in the wettability changing layer will be coupled with the first electrode layer while the silane coupling agent contained in the luminescent layer will be coupled with the wettability changing layer. Therefore, the adhesion properties, between the first electrode layer, the wettabiltiy changing layer and the luminescent layer, can be enhanced. Accordingly, degradation of the life properties caused by interlayer peeling or detachment during operation of the EL element and the like can be prevented.

It is noted that the expression “the quantum dots, around each of which the silane coupling agent is attached, are used in the luminescent layer” implies either of the case in which the silane coupling agent attached around each quantum dot is the silane coupling agent itself, the case in which such an agent is a hydrolyzate of the silane coupling agent, and the case in which such an agent is a condensate obtained through the hydrolysis (i.e., the condensate of the hydrolyzate) of the silane coupling agent. Namely, around each quantum dot in the luminescent layer, the silane coupling agent itself may be attached, or the hydrolyzate of the silane coupling agent may be attached, or otherwise the condensate of the hydrolyzate of the silane coupling agent may be attached. Alternatively or additionally, the silane coupling agent itself, hydrolyzate of the silane coupling agent and condensate of the hydrolyzate of the silane coupling agent may be present as a mixture thereof in the fluorescent layer.

In the case in which the luminescent layer contains the condensate of the hydrolyzate of the silane coupling agent, this luminescent layer can be used as a cured layer. Consequently, upon forming the positive-hole-injecting-transporting layer or forming electron-injecting-and-transporting layer by using each corresponding coating liquid on such a cured luminescent layer, the positive-hole-injecting-and-transporting layer or electron-injecting-and-transporting layer can be stably laminated on the luminescent layer, while preventing the luminescent layer from being dissolved into the solvent contained in the coating liquid for forming the positive-hole-injecting-and-transporting layer or electron-injecting-and-transporting layer.

The substrate, first electrode layer, luminescent layer and second electrode layer have been discussed in detail in the above section “A. Manufacturing method for the EL element,” respectively. Therefore, the explanation on these components is now omitted. Hereinafter, other constructional features will be described.

### 1. Wettability Changing Layer

The wettability changing layer of this invention is formed on the first electrode layer and configured such that the wettability thereof can be changed by the effect of the photocatalyst associated with the irradiation with energy. In addition, this wettability changing layer has the wettability changing pattern formed on the surface thereof, wherein the wettability changing pattern is composed of the lyophilic regions, each located on the pattern of the first electrode layer and containing polysiloxane, and the liquid-repellent regions, each located on each opening of the pattern of the first electrode layer and containing organopolysiloxane containing fluorine.

The lyophilic regions and liquid-repellent regions have been respectively described in detail in the above section “Wettability-changing-pattern-forming step” of “A. Manufacturing method for the EL element” in the first embodiment. Therefore, the explanation on these regions is now omitted.

Each liquid-repellent region contains organopolysiloxane containing fluorine, while each lyophilic regions contains polysiloxane. As described above, fluorine renders the surface energy significantly lowered. Therefore, a surface of a material containing a lot of fluorine tends to exhibit considerably reduced critical surface tension. In this invention, the content of fluorine in each liquid-repellent region can be considered to be greater than the content of fluorine in each lyophilic regions. Accordingly, the critical surface tension of each lyophilic regions can be considered to be greater than the critical surface tension of each liquid-repellent region. The wettability changing layer has the wettability changing pattern formed on the surface thereof, wherein this pattern is composed of such liquid-repellent regions and lyophilic regions. Thus, upon forming the luminescent layer on the wettability changing layer, the luminescent layer can be formed only on each lyophilic regions, by utilizing such a difference in the wettability between each liquid-repellent region and each lyophilic regions.

The content of fluorine in both of the lyophilic regions and liquid-repellent regions have been described in detail in the above section “Wettability-changing-pattern-forming step” of “A. Manufacturing method for the EL element” in the first embodiment. Therefore, the explanation on this matter is now omitted.

As the organopolysiloxane containing fluorine for constituting each liquid-repellent region, for example, (1) organopolysiloxane, which can be obtained through hydrolysis and polycondensation of chloro- or alkoxy-silanes and the like monomers in a sol-gel reaction or the like, thus exhibiting considerably high strength, (2) organopolysiloxane, in which reactive silicones, each having excellent water-repellent properties and/or oil-repellent properties, are cross-linked together, and the like organopolysiloxane can be mentioned. Such organopolysiloxane containing fluorine has the wettabiltiy that can be appropriately changed by the effect of the photocatalyst associated with the irradiation with energy and also has a main chain that is unlikely to be degraded or decomposed by the effect of the photocatalyst. Therefore, this organopolysiloxane can be suitably used for the liquid-repellent regions.

In the case (1) described above, the organopolysiloxane containing fluorine is preferably a condensate obtained through hydrolysis or co-hydrolysis of one or two or more of silicon compounds, each expressed by the following general formula:

YnSiX(4−n),

in which Y is an alkyl group, fluoroalkyl group, vinyl group, amino group, phenyl group or epoxy group, X is an alkoxyl group, acetyl group or halogen when Y is the fluoroalkyl group, or X is fluorine when Y is the alkyl group, vinyl group, amino group phenyl group or epoxy group, and n is an integer of from 0 to 3. The number of carbon atoms included in the group designated by Y is preferably within a range of from 1 to 20. Preferably, the alkoxyl group designated by X is a methoxy group, ethoxy group, propoxy group or butoxy group. Specifically, as the silicon compound expressed by the above general formula, those disclosed in JP2000-249821A can be used.

Especially, it is preferable to use polysiloxane containing the fluoroalkyl group as the organopolysiloxane containing fluorine. As such a polysiloxane containing the fluoroalkyl group, for example, a codensate obtained through hydrolysis or co-hydrolysis of one or two or more of fluoroalkylsilanes described in JP2000-249821A can be mentioned. Namely, a material, which is generally known and commonly used as a fluoro-type silane coupling agent can be used.

By using the polysiloxane containing the fluoroalkyl group, the liquid-repellent properties of each liquid-repellent region can be significantly enhanced. As such, film formation of the luminescent layer on each liquid-repellent region can be securely prevented. Therefore, the luminescent layer can be formed only on each lyophilic regions.

Whether or not the polysiloxane containing the fluoroalkyl group is contained in each liquid-repellent region can be observed by the X-ray photoelectron spectrometry, Rutherford back-scattering spectrometry, nuclear magnetic resonance spectrometry or mass spectrometry.

As the reactive silicone in the case (2), which is used for the organopolysiloxane containing fluorine, a compound having a skeleton expressed by the following chemical formula can be mentioned.

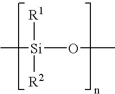

In the above chemical formula, n is an integer of 2 or greater, R¹, R² are independently a substituted or non-substituted alkyl group, alkenyl group, aryl group or cyanoalkyl group, each having 1 to 10 carbon atoms, wherein fluorinated phenyl groups are included in the above skeleton at a molar ratio of 40% or less. Preferably, the skeleton includes methyl groups as the R¹, R², because such a molecular structure can make the surface energy the minimum. In this case, it is preferred that the methyl groups are included in this skeleton at a molar ratio of 60% or greater. In addition, this skeleton includes at least one reactive group, such as a hydroxyl group, in its molecular chain, at terminal ends and/or side chains thereof.

Alternatively or additionally, each liquid-repellent region may contain a relatively stable organosilicone compound (e.g., dimethylpolysiloxane) that causes no cross-linking reaction, together with the aforementioned organopolysiloxane containing fluorine.

Each lyophilic regions contains less fluorine than each liquid-repellent region. For instance, in the case of utilizing the effect of the photocatalyst associated with the irradiation with energy, as shown in FIGS. 1(b), 1(c) or FIGS. 5(b), 5(c), in each portion, irradiated with the energy, of the wettability changing layer 4, each side chain including fluorine of the organopolysiloxane containing fluorine will be decomposed, as such decreasing the content of fluorine, thereby to change the wettability, such that the contact angle relative to the liquid will be lowered. Namely, such an organopolysiloxane containing fluorine, in which the side chain thereof including fluorine has been decomposed by the effect of the photocatalyst associated with the irradiation with energy, can be considered as the polysiloxane that constitutes each lyophilic regions.

Similar to each liquid-repellent region, each lyophilic regions may contain a relatively stable organosilicone compound (e.g., dimethylpolysiloxane) that causes no cross-linking reaction, together with the aforementioned polysiloxane.

Other than the aforementioned organopolysiloxane and/or polysiloxane containing fluorine, suitable surfactants and/or other additives, as described in JP2000-249821A, may be added to the lyophilic regions and/or liquid-repellent regions.

In regard to positions of the liquid-repellent regions and lyophilic regions, each liquid-repellent region may be located on each opening of the pattern of the first electrode layer, while each liquid-philic region may be located on the pattern of the first electrode layer.

The shape of the pattern including the liquid-repellent regions and lyophilic regions can be suitably selected, corresponding to the pattern-like shape of the first electrode layer. For instance, in the case in which the first electrode layer is formed into a stripe shape, the lyophilic regions will be formed, respectively corresponding to such a stripe pattern of the first electrode layer. Alternatively, for instance, in the case in which the first electrode layer is formed into a mosaic pattern including multiple picture elements, the lyophilic regions may be formed into a stripe pattern or otherwise may be formed into such a mosaic pattern. In either case, the regions other than such lyophilic regions will be the liquid-repellent regions, respectively, on the surface of the wettability changing layer.

The wettability changing layer should have at least the wettability changing pattern on the surface thereof, wherein the wettability changing pattern is composed of the liquid-repellent regions and lyophilic regions as respectively described above. Usually, in such a wettabiltiy changing layer, portions other than the lyophilic regions on the surface have the same construction and/or composition as that of the liquid-repellent regions on the surface, respectively. Namely, in the wettability changing layer, the portions other than the lyophilic regions on the surface contain organopolysiloxane containing fluorine, respectively.

In this case, the wettability changing layer may contain or may not contain the photocatalyst. The wettability changing layer containing the photocatalyst is the same as the wettability changing layer described in the above section “A. Manufacturing method for the EL element” of the first embodiment. Meanwhile, the wettability changing layer not containing the photocatalyst is the same as the wettability changing layer described in the above section “A. Manufacturing method for the EL element” of the second embodiment.

The method and the like means for forming the wettability changing layer containing the photocatalyst has been described in detail in the above section “A. Manufacturing method for the EL element” of the first embodiment, while the method and the like means for forming the wettability changing layer not containing the photocatalyst have been described in detail in the above section “A. Manufacturing method for the EL element” of the second embodiment. Therefore, the description on these matters is now omitted.

In addition, since the film thickness and the like of the wettability changing layer have been detailed in the above “A. Manufacturing method for the EL element,” the explanation on this matter is now omitted.

### 2. Other Layers

In the invention, the positive-hole injecting and transporting layer may be provided between the first electrode layer and the luminescent layer.

In the case in which the positive-hole injecting and transporting layer is the positive-hole transporting layer, the positive-hole transporting layer and luminescent layer may be separated into each phase. Consequently, the efficiency of emission and life properties can be significantly enhanced.

Since the positive-hole injecting and transporting layer and the case, in which the positive-hole transporting layer and luminescent layer are separated into each phase, have been discussed in detail in the above section “A. Manufacturing method for the EL element.” Therefore, the description on these matters is now omitted.

Alternatively or additionally, in this invention, the electron injecting and transporting layer may be provided between the luminescent layer and the second electrode layer. It is noted that the electron injecting and transporting layer has been discussed in the above section “A. Manufacturing method for the EL element.” Therefore, the description on this layer is now omitted.

Furthermore, the insulating layer may be provided on each opening of the pattern of the first electrode layer on the substrate. Again, such an insulating layer has been described in the above section “A. Manufacturing method for the EL element.” Therefore, the explanation of this layer is also omitted now.

It should be noted that the present invention is not limited to the embodiments described above. Namely, these embodiments have been described, by way of example only, and any modification and/or variation having substantially the same construction as well as providing substantially the same effect, as those claimed herein, should be construed to fall within the scope of this invention.

### EXAMPLES

Hereinafter, several examples will be described specifically, with reference to the drawings.

### Example 1

### (Formation of the Optically Transparent Electrode)

An ITO film, as the optically transparent electrode, was formed on a washed glass substrate, by spattering, with a film thickness of 1500 Å. Thereafter, the ITO was patterned, by photolithography, with a line width of 300 μm and a pitch of 100 μm.

### (Formation of the Insulating Layer)

A negative-type resist (produced by SHINNITTETU-KAGAKU Co., Ltd., V259PA) was coated, by spin coating, with a dried film thickness of 1 μm, on the substrate having the ITO film formed thereon into a pattern-like shape. Thereafter, the resist coated on the substrate was baked for 1 hour at 120° C. Then, the resist was exposed to UV light of 365 nm at 500 mJ, via a proper photomask, centered on each pitch portion having no ITO film, over a width of 100 μm. This exposure process was performed, with a 1 mm gap provided between the photomask and the substrate. Subsequently, the so-exposed resist was developed, for 40 seconds, with an organic alkaline developing solution (produced by SHINNITTETU-KAGAKU Co., Ltd., V2590D), and the resist still remaining on the substrate was then baked for 1 hour at 160° C., thereby to form the insulating layer.

### (Formation of the Wettability Changing Layer)

The wettability-changing-layer-forming coating liquid was prepared by mixing the following materials.

### <Composition of the Wettability-Changing-Layer-Forming Coating Liquid>.

Titanium-dioxide-sol liquid (produced by IHSIHARA-SANGYO Co., Ltd., STS-01) 3 (parts by weight)
Tetraethoxysilane 1 (parts by weight)
2N hydrochloric acid 40 (parts by weight)
Isopropyl alcohol 75 (parts by weight)
Fluoroalkoxysilane (produced by TOCHEM-PRODUCTS Co., LTD, MF-160E) 7.5 (parts by weight)

The so-prepared wettability-changing-layer-forming coating liquid was then coated on the substrate by a spin coater, and thereafter the coated liquid was dried for 10 minutes at 150 ° C., thereby forming a transparent wettability changing layer having a film thickness of 60 nm. Subsequently, the wettability changing layer was irradiated by a high-pressure mercury lamp (254 nm, 365 nm), with luminance of 70 nW/cm², for 50 seconds, via a proper photomask, so as to form the wettability changing pattern composed of the lyophilic regions and liquid-repellent regions.

### (Formation of the Luminescent Layer)

On the lyophilic regions, a dispersion of the quantum dots for red color emission (produced by EVIDENT-TECHNOLOGY Co., Ltd., Maple-Red Orange), a dispersion of the quantum dots for green color emission (produced by EVIDENT-TECHNOLOGY Co., Ltd., Adirondack Green), and a dispersion of the quantum dots for blue color emission (produced by EVIDENT-TECHNOLOGY Co., Ltd., Lake Placid Blue), were coated by the injection method, respectively. Then, the resultant coated films were dried for 30 minutes at 80° C., so as to form the luminescent layers for such three colors, respectively.

### (Formation of the Electron Transporting Layer)

Thereafter, by vacuum deposition, a TAZ film having a thickness of 20 nm was formed on the luminescent layer, and an Alq film having a thickness of 20 nm was then formed thereon.

### (Formation of a Metallic Electrode)

After the formation of the electron transporting layer, a LiF film (thickness: 5 nm) and an Al film (thickness: 1000 Å) were formed, respectively, by vacuum deposition, with a proper mask. In this case, the LiF film and Al film were respectively formed into a pattern orthogonal to the pattern of the ITO film. In this way, the EL element was prepared.

### (Assessment)

Then, terminals of the ITO electrode and Al electrode were respectively connected with a voltage source, and voltage higher than 5V was applied to each terminal. As a result, emission was observed, from the red-color luminescent layer at a peak of 620 nm, from the green-color luminescent layer at a peak of 520 nm, and from the blue-color luminescent layer at a peak of 490 nm, respectively. Each emission was substantially equivalent to an emission spectrum (or photo-luminescence spectrum) of the CdSe/ZnS quantum dots, for each corresponding color, protected by the TOPO. In this way, the obtained EL element was assessed to exhibit highly improved stability, efficiency and luminance, thus demonstrating significantly enhanced applicability of the patterning.

### Example 2

In this Example 2, the EL element was prepared in the same manner as in the Example 1, except that the luminescent layer was formed as follows.

### (Formation of the Luminescent Layer)

### 1. Preparation of a Red-Color-Luminescent-Layer-Forming Coating Liquid

A suitable silane coupling agent was added to the dispersion of the quantum dots for red color emission (produced by EVIDENT-TECHNOLOGY Co., Ltd., Maple-Red Orange) in order to couple the ligands around each quantum dot.

More specifically, 5 g of tetramethoxy silane (produced by SHIN-ETSU-KAGAKU Co., Ltd., LS-540), 1 g of phenyltrimethoxysilane (produced by SHIN-ETSU-KAGAKU Co., Ltd., LS-2750) and 2 g of 0.01N HCl were mixed together, with stirring for 12 hours at a room temperature, so as to obtain a copolymer compound (i.e., silane coupling agent). Thereafter, this copolymer compound was dissolved and stirred in toluene, so as to obtain a 10wt % toluene solution of the silane coupling agent.

Then, 1 g of the aforementioned dispersion of the quantum dots was dropped into 2 g of the 10 wt % toluene solution of the silane coupling agent, with stirring, under an argon gas atmosphere, at a room temperature (26° C.). After this reaction mixture was further stirred for 12 hours, the argon gas atmosphere was replaced by an air atmosphere, and toluene, corresponding to an amount of the toluene having been vaporized and scattered away, was supplemented. Thereafter, 8 g of ethanol was added to the reaction mixture. After separation of a precipitate obtained by centrifugal separation from the reaction mixture, purification by precipitation was conducted in the following procedure.

In this case, the precipitate was mixed with 4 g of toluene to form a dispersion, and 10 g of ethanol was then added to the so-obtained dispersion. In this way, a considerably purified precipitate was obtained.

Thereafter, the so-purified precipitate was separated from the liquid by the centrifugal separation, thereby to obtain purified quantum dots each protected by the silane coupling agent.

In this way, a red-color-luminescent-layer-forming coating liquid was prepared, in which such purified quantum dots each protected by the silane coupling agent were dispersed in toluene.

### 2. Preparation of a Green-Color-Luminescent-Layer-Forming Coating Liquid

A green-color-luminescent-layer-forming coating liquid was prepared, in the same manner as in the preparation of the red-color-luminescent-layer-forming coating liquid, by using the dispersion of the quantum dots for green color emission (produced by EVIDENT-TECHNOLOGY Co., Ltd., Adirondack Green).

### 3. Preparation of a Blue-Color-Luminescent-Layer-Forming Coating Liquid

A blue-color-luminescent-layer-forming coating liquid was prepared, in the same manner as in the preparation of the red-color-luminescent-layer-forming coating liquid, by using the dispersion of the quantum dots for blue color emission (produced by EVIDENT-TECHNOLOGY Co., Ltd., Lake Placid Blue).

### 4. Formation of the Luminescent Layer

The so-prepared red-color-luminescent-layer-forming coating liquid, green-color-luminescent-layer-forming coating liquid and blue-color-luminescent-layer-forming coating liquid were coated on the substrate by the injection method, one after another, and the resultant coated films were then dried and cured for 30 minutes at 100° C., so as to form the luminescent layers for such three colors, into a pattern-like shape.

### (Assessment)

Then, the terminals of the ITO electrode and Al electrode were respectively connected with a voltage source, and voltage higher than 4V was applied to each terminal. As a result, emission was observed, from the red-color luminescent layer at a peak of 620 nm, from the green-color luminescent layer at a peak of 520 nm, and from the blue-color luminescent layer at a peak of 490 nm, respectively. Each emission was substantially equivalent to an emission spectrum (or photo-luminescence spectrum) of the CdSe/ZnS quantum dots, for each corresponding color, protected by the TOPO. In this way, the obtained EL element was verified to exhibit highly improved stability, efficiency and luminance, thus proving significantly enhanced applicability of the patterning.

### Example 3

### (Formation of the Insulating Layer)

A suitable substrate was prepared, on which the ITO film, as the first electrode layer, was patterned on a glass substrate, with a line width of 80 μm, a space width of 20 μm and a pitch of 100 μm.

Subsequently, a positive-type photosensitive material (produced by TOKYO-OUKA Co., Ltd., OFPR-800) was coated, by spin coating, over the whole surface of the substrate, with a film thickness of 1.5 μm, so as to form the insulating film. Then, the photosensitive material was exposed to appropriate energy, via a proper photomask designed such that each opening of the light shielding part thereof has a 70 μm×70 μm rectangular shape corresponding to the pattern of the ITO film. After this exposure process, the photosensitive material was developed by using an alkaline developing liquid (produced by TOKYO-OUKA Co., Ltd., NMD-3). Then, the remaining photosensitive material on the substrate was heated and cured for 30 minutes at 250° C., so as to obtain the insulating film.

### (Formation of the Wettability Changing Layer)

The wettability-changing-layer-forming coating liquid having the following composition was prepared.

### <Composition of the Wettability-Changing-Layer-Forming Coating Liquid>

Organoalkoxysilane
(produced by GE-TOSHIBA SILICONE Co., Ltd., TSL8113) 0.4 (parts by weight)
Fluoroalkylsilane
(produced by GE-TOSHIBA SILICONE Co., Ltd., TSL8233) 0.3 (parts by weight)
Isopropyl alcohol 480 (parts by weight)

The so-prepared wettability-changing-layer-forming coating liquid was then coated on the substrate by spin coating, and thereafter the coated liquid was heated and dried for 10 minutes at 150° C., so as to promote the hydrolysis and polycondensation. In this way, the coated liquid was adequately cured, thereby obtaining the wettability changing layer having a thickness of 10 nm.

### (Preparation of the Photocatalyst-Processing-Layer Substrate)

Thereafter, a proper photomask, designed such that each opening of the light shielding part will have a 85 μm×85 μm rectangular shape, was prepared, corresponding to the pattern of the ITO film. Then, the photocatalyst-processing-layer-forming coating liquid of the following composition was coated on the photomask, and heated and dried for 10 minutes at 150° C., so as to promote the hydrolysis and polycondensation. In this way, an optically transparent photocatalyst processing layer having a thickness of 2000 Å was formed, in which the photocatalyst was firmly fixed to the organosiloxane.

### <Composition of the Photocatalyst-Processing-Layer-Forming Coating Liquid>

Titanium dioxide (produced by ISHIHARA-SANGYO Co., Ltd., ST-K01) 2 (parts by weight)
Organoalkoxysilane
(produced by GE-TOSHIBA SILICONE Co., Ltd., TSL8113) 0.4 (parts by weight)
Isopropyl alcohol 3 (parts by weight)

### (Formation of the Wettability Changing Pattern)

First, the photocatalyst-processing-layer substrate was positioned over the substrate for the wettability changing layer, such that each opening of the light shielding part of the photocatalyst-processing-layer substrate corresponds to the pattern of the ITO film formed on the substrate for the wettability changing layer. In this case, the gap between the photocatalyst-processing-layer substrate and the wettability changing layer was set at 20 μm. After such setting, the wettability changing layer was exposed to light of 253 nm of 200 mJ/cm², coming from a rear face side of the photocatalyst-processing-layer substrate, by using a UV exposure apparatus including a high-pressure mercury lamp as a light source and provided with the positioning means for positioning both of the photocatalyst-processing-layer substrate and the substrate for the wettability changing layer.

Thereafter, the contact angles relative to the liquid of each exposed portion and each non-exposed portion of the wettability changing layer were measured respectively, by using a contact angle meter (produced by KYOWA-KAIMEN-KAGAKU Co. Ltd.). As a result, the contact angle measured in each exposed portion (or liquid-philic portion) was less than 20° relative to toluene, while the contact angle in each non-exposed portion (or liquid-repellent region) was 35° or greater relative to the toluene.

### (Formation of the Luminescent Layer)

The red-color-luminescent-layer-forming coating liquid, green-color-luminescent-layer-forming coating liquid and blue-color-luminescent-layer-forming coating liquid, used in the Example 2, were respectively coated, by the injection method, on the lyophilic regions or exposed regions of the wettability changing layer, and the resultant coated films were then dried for 30 minutes at 80° C. in the air, so as to form the luminescent layers for such three colors, into a pattern like shape, respectively.

### (Formation of the Electron Transporting Layer)

Thereafter, by vacuum deposition, a TAZ film having a thickness of 20 nm was formed on the luminescent layer, and an Alq3 film having a thickness of 20 nm was then formed thereon.

### (Formation of the Metallic Electrode)

After the formation of the electron transporting layer, a LiF film (thickness: 5 nm) and an Al film (thickness: 1000 Å) were formed, respectively, by vacuum deposition, with a proper mask. In this case, the LiF film and Al film were respectively formed into a pattern-like shape orthogonal to the pattern of the ITO film. In this way, the EL element was prepared.

### (Assessment)

Then, the terminals of the ITO electrode and Al electrode were respectively connected with a voltage source, and voltage higher than 5V was applied to each terminal. As a result, emission was observed, from the red-color luminescent layer at a peak of 620 nm, from the green-color luminescent layer at a peak of 520 nm, and from the blue-color luminescent layer at a peak of 490 nm, respectively. Each emission was substantially equivalent to an emission spectrum (or photo-luminescence spectrum) of the CdSe/ZnS quantum dots, for each corresponding color, protected by the TOPO. In this way, the obtained EL element was assessed to exhibit highly improved stability, efficiency and luminance, thus demonstrating significantly enhanced applicability of the patterning.

### Example 4

In this example, the EL element was prepared in the same manner as in the Example 3, except that the positive-hole injecting layer was formed on each lyophilic regions or each exposed portion of the wettability changing layer, prior to the formation of the luminescent layer.

### (Formation of the Positive-Hole Injecting Layer)

First, an aqueous dispersion (produced by STALK Co., Ltd., Baytron P CH-8000) consisting of poly(3,4-alkenedioxanethiophene) and polystyrenesulfonic acid (PEDOT/PSS) was diluted with isopropyl alcohol, so as to prepare a positive-hole-injecting-layer-forming coating liquid. Thereafter, viscosity and surface tension of this positive-hole-injecting-layer-forming coating liquid were measured, respectively. As a result, the viscosity was 7 mPa·s, and the surface tension was 37 dyn/cm. The positive-hole-injecting-layer-forming coating liquid was then coated, by the injection method, on each lyophilic regions or each exposed portion of the wettability changing layer, such that the film thickness will be 80 nm after a drying process. Thereafter, the coated film was dried for 10 minutes at 150° C. in the air. In this way, the positive-hole injecting layer was formed.

### (Assessment)

Then, the terminals of the ITO electrode and Al electrode were respectively connected with a voltage source, and voltage higher than 4V was applied to each terminal. As a result, emission was observed, from the red-color luminescent layer at a peak of 620 nm, from the green-color luminescent layer at a peak of 520 nm, and from the blue-color luminescent layer at a peak of 490 nm, respectively. Each emission was substantially equivalent to an emission spectrum (or photo-luminescence spectrum) of the CdSe/ZnS quantum dots, for each corresponding color, protected by the TOPO. In this way, the obtained EL element was assessed to exhibit highly improved stability, efficiency and luminance, thus demonstrating significantly enhanced applicability of the patterning.

### Example 5

In this example, the EL element was prepared in the same manner as in the Example 3, except that the luminescent layer was formed as follows, and that the electron injecting layer was not formed.

### (Formation of the Luminescent Layer)

### 1. Preparation of the Red-Color-Luminescent-Layer-Forming Coating Liquid

The red-color-luminescent-layer-forming coating liquid was prepared by mixing and dispersing the quantum dots protected by the silane coupling agent, which had been prepared, in the example 2, by using the dispersion (produced by EVIDENT-TECHNOLOGY Co., Ltd., Maple-Red Orange) of the quantum dots for red color emission, triazole (electron transporting material) and TPD (positive-hole transporting material), in toluene. In this case, the mixing ratio of the quantum dots, each protected by the silane coupling agent, was 40 parts by weight, the ratio of triazole was 30 parts by weight, and the ratio of TPD was 30 parts by weight, respectively.

### 2. Preparation of the Green-Color-Luminescent-Layer-Forming Coating Liquid

The green-color-luminescent-layer-forming coating liquid was prepared, in the same manner as in the preparation of the red-color-luminescent-layer-forming coating liquid, by using the quantum dots each protected by the silane coupling agent, which had been prepared, in the Example 2, by using the dispersion (produced by EVIDENT-TECHNOLOGY Co., Ltd., Adirondack Green) of the quantum dots for green color emission.

### 3. Preparation of the Blue-Color-Luminescent-Layer-Forming Coating Liquid

The blue-color-luminescent-layer-forming coating liquid was prepared, in the same manner as in the preparation of the red-color-luminescent-layer-forming coating liquid, by using the quantum dots each protected by the silane coupling agent, which had been prepared, in the Example 2, by using the dispersion (produced by EVIDENT-TECHNOLOGY Co., Ltd., Lake Placid Blue) of the quantum dots for green blue color emission.

### 4. Formation of the Luminescent Layer

The so-prepared red-color-luminescent-layer-forming coating liquid, green-color-luminescent-layer-forming coating liquid and blue-color-luminescent-layer-forming coating liquid were coated, one after another, by the injection method, on each lyophilic regions or each exposed portion of the wettability changing layer, and the resultant coated films were then dried for 30 minutes at 80° C. in the air, so as to form the luminescent layers for the three colors, into a pattern-like shape, respectively.

### (Assessment)

Then, the terminals of the ITO electrode and Al electrode were respectively connected with a voltage source, and voltage higher than 6V was applied to each terminal. As a result, emission was observed, from the red-color luminescent layer at a peak of 620 nm, from the green-color luminescent layer at a peak of 520 nm, and from the blue-color luminescent layer at a peak of 490 nm, respectively. Each emission was substantially equivalent to an emission spectrum (or photo-luminescence spectrum) of the CdSe/ZnS quantum dots, for each corresponding color, protected by the TOPO. In this way, the obtained EL element was verified to exhibit highly improved stability, efficiency and luminance, thus demonstrating significantly enhanced applicability of the patterning.

1. A manufacturing method for an electroluminescent element, the method comprising:
a wettability-changing-layer-forming step for forming a wettability changing layer containing a photocatalyst, on a substrate having a first electrode layer formed thereon, wherein wettability of the wettability-changing layer is changed by an effect of the photocatalyst associated with irradiation with energy;
a wettability-changing-pattern forming step for forming a wettability changing pattern composed of lyophilic regions and liquid-repellent regions, on a surface of the wettability changing layer, by irradiating the wettability changing layer with energy in a patterning manner; and
a luminescent-layer-forming step for forming a luminescent layer onto each lyophilic region by coating a luminescent-layer-forming coating liquid containing quantum dots, around each of which ligands are attached, to the wettability changing layer with the wettability changing pattern.

2. A manufacturing method for an electroluminescent element, the method comprising:
a wettability-changing-layer-forming step for forming a wettability changing layer, on a substrate having a first electrode layer formed thereon, wherein the wettability of the wettability changing layer is changed by an effect of a photocatalyst associated with irradiation with energy;
a wettability-changing-pattern-formign step for forming a wettability changing pattern composed of lyophilic regions and liquid-repellent regions, on a surface of the wettability changing layer, by irradiating the wettability changing layer with energy in a patterning manner, after a photocatalyst-processing-layer base, on which a photocatalyst-processing layer containing at least the photocatalyst is formed, is located over the surface of the wettability changing layer, with a gap that allow the effect of the photocatalyst associated with the irradiation with energy to be exerted on the wettability changing layer; and
a luminescent-layer-forming step for forming a luminescent layer onto each lyophilic region by coating a luminescent-layer-forming coating liquid containing the quantum dots, around each of which the ligands are attached, to the wettability changing layer with the wettability changing pattern.

3. The manufacturing method for the electroluminescent element according to claim 1 or 2, wherein the ligands include a silane coupling agent.

4. The manufacturing method for the electroluminescent element according to claim 3, wherein the silane coupling agent includes a silicon compound expressed by a general formula: YnSiX(4−n), in which Y is an alkyl group, fluoroalkyl group, vinyl group, amino group, phenyl group or epoxy group, X is an alkoxyl group, acetyl group or halogen, and n is an integer of from 0 to 3.

5. The manufacturing method for the electroluminescent element according to claim 3, wherein the silane coupling agent includes a silicon compound expressed by a general formula: YnSiX(4−n), in which Y is a functional group, which can exhibit positive-hole transporting properties, wherein each positive hole can be coupled, directly or via a vinyl group or phenyl group, with this functional group, or another functional group, which can exhibit electron transporting properties, wherein each electron can be coupled, directly or via a vinyl group or phenyl group, with this functional group, or still another functional group, which can exhibit both of the positive-hole transporting properties and electron transporting properties, wherein each positive hole or electron can be coupled, directly or via a vinyl group or phenyl group, with this functional group, X designates an alkoxyl group, acetyl group or halogen, and n is an integer of 0 to 3.

6. The manufacturing method for the electroluminescent element according to claim 3, wherein, in the luminescent-layer-forming step, the luminescent-layer-forming coating liquid is cured after it is coated.

7. The manufacturing method for the electroluminescent element according to claim 1 or 2, wherein the luminescent-layer-forming coating liquid further contains at least either one of a positive-hole transporting material and an electron transporting material.

8. The manufacturing method for the electroluminescent element according to claim 1 or 2, wherein each quantum dot is composed of a core portion formed from semiconductor fine particles, and a shell portion formed from a material having an energy band gap greater than that of the semiconductor fine particles.

9. The manufacturing method for the electroluminescent element according to claim 1 or 2, wherein a method for coating the luminescent-layer-forming coating liquid includes a discharge method.

10. The manufacturing method for the electroluminescent element according to claim 1 or 2, wherein the wettability changing layer contains organopolysiloxane, which is a condensate obtained through hydrolysis or co-hydrolysis of one or two or more of silicon compounds, each expressed by a general formula: YnSiX(4−n), in which Y is an alkyl group, fluoroalkyl group, vinyl group, amino group, phenyl group or epoxy group, X is an alkoxyl group, acetyl group or halogen, and n is an integer of from 0 to 3.

11. An electroluminescent element, comprising:
a substrate;
a first electrode layer formed in a pattern-like shape on the substrate;
a wettabiltiy changing layer formed on the first electrode layer, such that wettability of the wettability changing layer is changed by an effect of a photocatalyst associated with irradiation with energy, wherein the wettability changing layer has lyophilic regions, each located corresponding to the pattern of the first electrode and containing polysiloxane, and has liquid-repellent regions, each located corresponding to each opening of the pattern of the first electrode layer and containing organopolysiloxane containing fluorine;
a luminescent layer formed on each lyophilic regions of the wettability changing layer; and
a second electrode layer formed on the luminescent layer,
wherein quantum dots, around each of which a silane coupling agent is attached, are used for the luminescent layer.

12. The electroluminescent element according to claim 11, wherein the luminescent layer contains a condensate obtained through hydrolysis of the silane coupling agent, and is appropriately cured.

13. The electroluminescent element according to claim 12, wherein the condensate obtained through hydrolysis of the silane coupling agent is organopolysiloxane, which is a condensate obtained through hydrolysis or co-hydrolysis of one or two or more of silicon compounds, each expressed by a general formula: YnSiX(4−n), in which Y is an alkyl group, fluoroalkyl group, vinyl group, amino group, phenyl group or epoxy group, X is an alkoxyl group, acetyl group or halogen, and n is an integer of from 0 to 3.

14. The electroluminescent element according to claim 12, wherein the condensate obtained through hydrolysis of the silane coupling agent is organopolysiloxane, which is a condensate obtained through hydrolysis or co-hydrolysis of one or two or more of silicon compounds, each expressed by a general formula: YnSiX(4−n), in which Y is a functional group, which can exhibit positive-hole transporting properties, wherein each positive hole can be coupled, directly or via a vinyl group or phenyl group, with this functional group, or another functional group, which can exhibit electron transporting properties, wherein each electron can be coupled, directly or via a vinyl group or phenyl group, with this functional group, or still another functional group, which can exhibit both of the positive-hole transporting properties and electron transporting properties, wherein each positive hole or electron can be coupled, directly or via a vinyl group or phenyl group, with this functional group, X designates an alkoxyl group, acetyl group or halogen, and n is an integer of 0 to 3.

15. The electroluminescent element according to claim 11, wherein each quantum dot is composed of a core portion formed from semiconductor fine particles, and a shell portion formed from a material having an energy band gap greater than that of the semiconductor fine particles.
